(19) United States
(12) Patent Application Publication
(10) Pub. No.: US 2026/0150405 A1
(43) Pub. Date: May 28, 2026

(54) BONDING LAYERS WITH HIGH THERMAL CONDUCTIVITY

(71) Applicant: Taiwan Semiconductor Manufacturing Company, Ltd., Hsinchu (TW)

(72) Inventors: Je-Ruei Wen, Hsinchu (TW); Che Chi Shih, Taoyuan City (TW); Kuan-Kan Hu, Hsinchu (TW); Wei-Yen Woon, Taoyuan City (TW)

(21) Appl. No.: 19/210,876

(22) Filed: May 16, 2025

Related U.S. Application Data
(60) Provisional application No. 63/725,782, filed on Nov. 27, 2024.

(51) Int. Cl. H10D 88/00; H10D 84/01

(52) U.S. Cl. CPC H10D 88/01; H10D 84/0149

(57) ABSTRACT

The present disclosure provides methods for integrating high-kappa dielectric material in stacked multi-gate device structure to improve thermal conductivity. A method according to the present disclosure includes forming a first multi-gate device structure, depositing a high-kappa dielectric layer over a substrate, bonding the high-kappa dielectric layer over the first multi-gate device structure, after the bonding of the high-kappa dielectric layer, removing the substrate, patterning the high-kappa dielectric layer to form a contact opening, forming a contact feature in the contact opening, bonding an epitaxial stack over the high-kappa dielectric layer and the contact feature; and performing further processes to form a second multi-gate device structure from the epitaxial stack. The epitaxial stack includes a plurality of first semiconductor layers interleaved by a plurality of second semiconductor layers.

### PRIORITY DATA

This application claims priority to U.S. Provisional Patent Application No. 63/725,782, filed on Nov. 27, 2024, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

As the semiconductor industry further progresses into advanced technology process nodes in pursuit of higher device density, higher performance, and lower costs, challenges from both fabrication and design issues have led to stacked device structure configurations, such as complementary field effect transistors (CFET) where multi-gate transistors are stacked vertically, one over the other. Heat dissipation is an important aspect when it comes to the stacked device structure configuration

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a stacked device structure having a high-kappa dielectric layer, according to one or more aspects of the present disclosure.

FIGS. 2-11 illustrate fragmentary cross-sectional views of a precursor structure undergoing various fabrication processes in the method of FIG. 1, according to one or more aspects of the present disclosure.

FIGS. 12-22 illustrate various stacked device structure formed using the method in FIG. 1.

FIG. 23 illustrates a flow chart of a method for forming a stacked device structure having two high-kappa dielectric layers bonded together, according to one or more aspects of the present disclosure.

FIGS. 24-43 illustrate fragmentary cross-sectional views of a precursor structure undergoing various fabrication processes in the method of FIG. 23, according to one or more aspects of the present disclosure.

FIGS. 44-54 illustrate various stacked device structure formed using the method in FIG. 23.

FIG. 55 illustrates a flow chart of a method for forming a stacked device structure having at least one high-kappa dielectric layer formed using selective deposition, according to one or more aspects of the present disclosure.

FIGS. 56-74 illustrate fragmentary cross-sectional views of a precursor structure undergoing various fabrication processes in the method of FIG. 55, according to one or more aspects of the present disclosure.

FIG. 75 illustrates a flow chart of a method for forming a stacked device structure having at least one high-kappa dielectric layer with contact features having rounded top corners, according to one or more aspects of the present disclosure.

FIGS. 76-87 illustrate fragmentary cross-sectional views of a precursor structure undergoing various fabrication processes in the method of FIG. 75, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (CFET). The multi-gate devices in a CFET may be FinFETs or GAA transistors. Due to limited routing areas, routing for a CFET is accomplished with both a frontside interconnect structure and a backside interconnect structure. The process to form the backside interconnect structure usually involves removal of the semiconductor substrate, which serves as a heat sink. Compared to multi-gate devices, stacked multi-gate devices tend generate more heat. The additional heat, compounded with the lack of a heat sink, poses challenges in heat dissipation for multi-gate devices.

The present disclosure provides methods to introduce one or more high-kappa dielectric layers in a CFET structure to serve as a heat sink. In one example process, a high-kappa dielectric layer is formed over a first multi-gate device structure. A contact feature is formed in the high-kappa dielectric layer. A superlattice structure that includes an alternating stack of first semiconductor layers and second semiconductor layers is bonded to the high-kappa dielectric layer. The superlattice structure is then patterned to form fin-shaped structures to undergo further processes to form a second multi-gate device structure. In another example process, a first high-Kappa dielectric layer is formed over a first multi-gate device structure. A contact feature is formed in the first high-kappa dielectric layer. A second high-kappa dielectric layer is formed over a second multi-gate device structure. The first multi-gate device structure and the second multi-gate device structure are then bonded together by way of the first high-kappa dielectric layer and the second high-kappa dielectric layer. The present disclosure also provides methods for patterning a high-kappa dielectric layer or depositing a high-kappa dielectric layer by selective deposition over a nucleation layer.

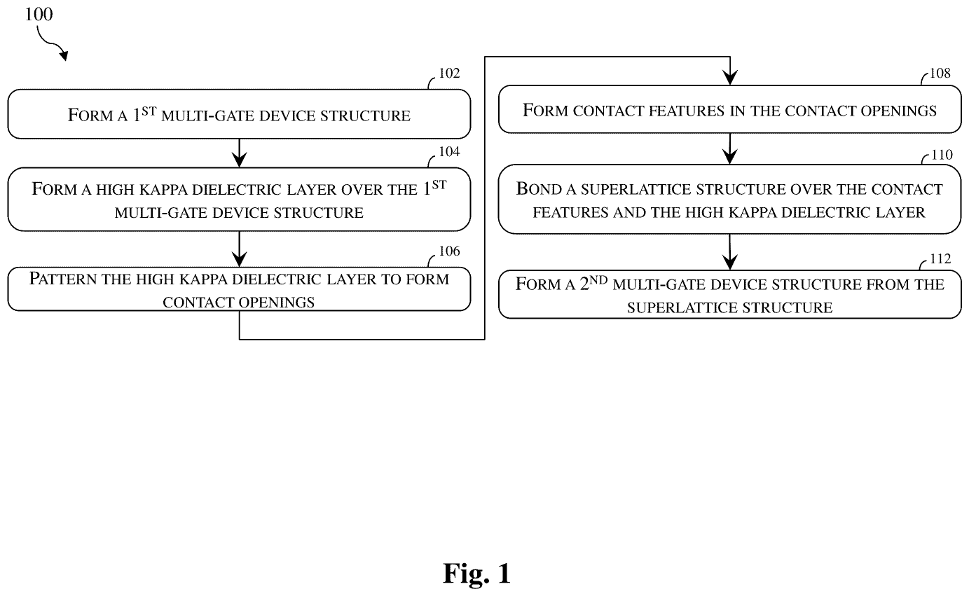

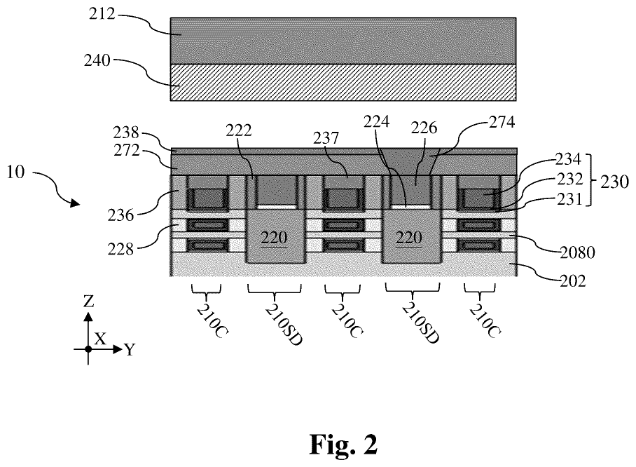

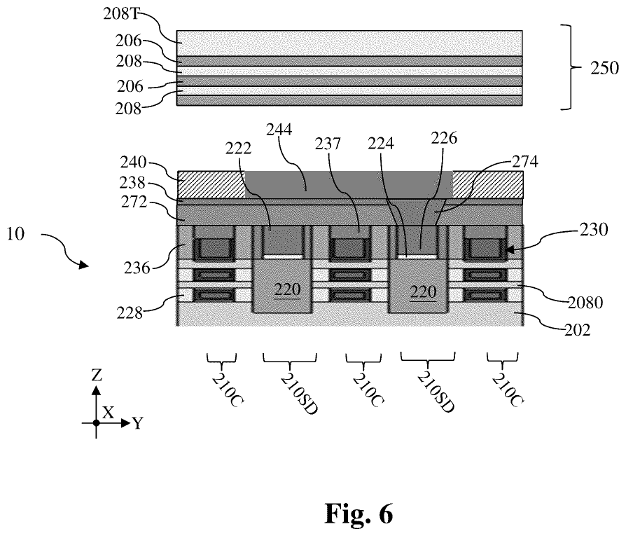

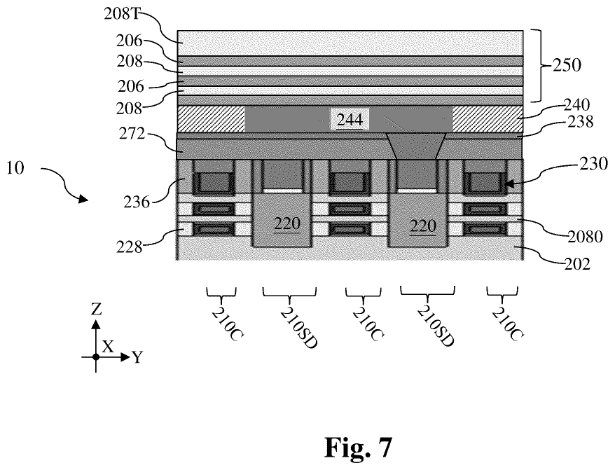

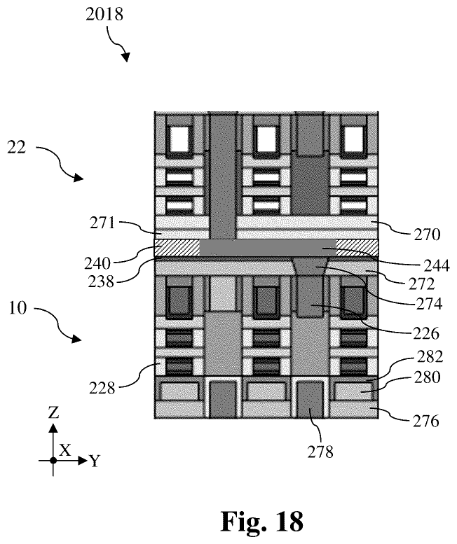

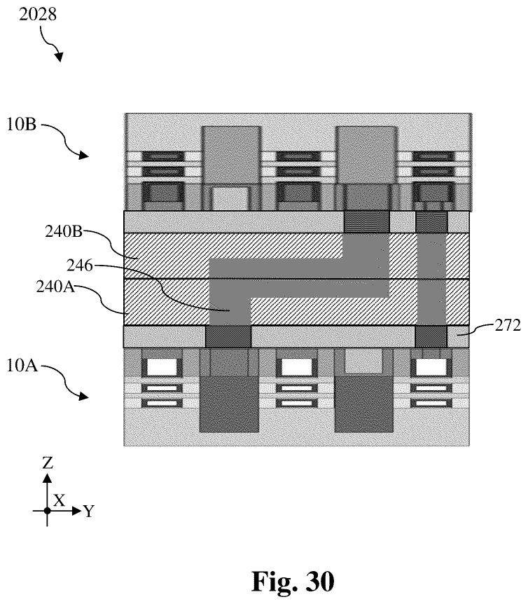

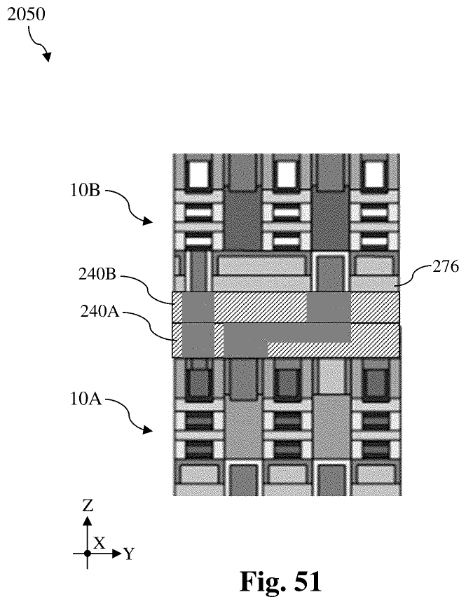

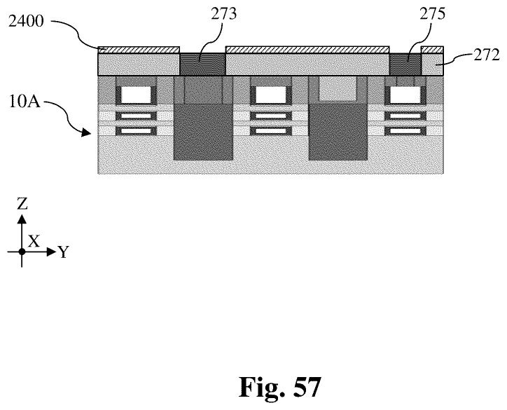

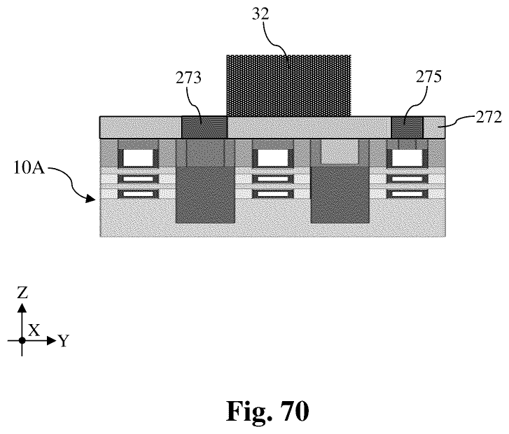

The various aspects of the present disclosure will now be described in more detail with reference to the figures. In that regard, FIGS. 1, 17, 50, and 69 are flowcharts illustrating methods 100, 300, 400, and 500 for forming a semiconductor device according to various aspects of the present disclosure. Methods 100, 300, 400, and 500 are merely examples and are not intended to limit the present disclosure to what is explicitly illustrated in method 100, 300, 400, or 500. Additional steps may be provided before, during and after method 100, 300, 400, or 500, and some steps described can be replaced, eliminated, or moved around for additional embodiments of the method. Not all steps are described herein in detail for reasons of simplicity. Method 100 is described below in conjunction with FIGS. 2-11, which are fragmentary cross-sectional views of a precursor structure 200 at different stages of fabrication according to embodiments of method 100. Method 300 is described below in conjunction with FIGS. 18-37, which are fragmentary cross-sectional views of a precursor structure 200 at different stages of fabrication according to embodiments of method 300. Method 400 is described below in conjunction with FIGS. 51-68, which are fragmentary cross-sectional views of a precursor structure 200 at different stages of fabrication according to embodiments of method 400. Method 500 is described below in conjunction with FIGS. 70-77, which are fragmentary cross-sectional views of a precursor structure 200 at different stages of fabrication according to embodiments of method 500. Because the precursor structure 200 will be fabricated into a semiconductor device upon conclusion of the fabrication processes, the precursor structure 200 may be referred to as a semiconductor device as the context requires. Additionally, throughout the present application and across different embodiments, like reference numerals denote like features with similar structures and compositions, unless otherwise excepted. Source/drain region(s) may refer to a source or a drain, individually or collectively, dependent upon the context.

Method 100 in FIG. 1 forms a high-kappa dielectric layer over a first multi-gate device structure, forms contact features in the high-kappa dielectric layer, bonds a superlattice structure to the high-kappa dielectric layer, and then forms a second multi-gate device structure from the superlattice structure. Because the second multi-gate device structure is formed subsequent to the formation of the first multi-gate device structure, method 100 may also be referred to as a sequential formation scheme.

Referring to FIGS. 1 and 2, method 100 includes a block 102 where a first multi-gate device structure 10 is formed. The first multi-gate device structure 10 includes an active region over a substrate 202. The active region includes nanostructures 2080 disposed over a base portion over patterned from the substrate 202. The active region may be divided into channel regions 210C and source/drain regions 210SD. Over a channel region 210C, a gate structure 230 wraps around each of the nanostructures 2080. The nanostructures 2080 are vertically stacked one over another and are interleaved by a plurality of inner spacer features 228. Gate spacers 236 are disposed along sidewalls of a portion of the gate structure 230 over the nanostructures 2080. The nanostructures 2080 extend between two bottom source/drain features 220. A contact etch stop layer (CESL) 222 is disposed over the bottom source/drain feature 220. A source/drain contact 226 extends through the CESL 222 to interface the bottom source/drain feature 220 by way of a bottom silicide feature 224. A self-aligned capping (SAC) layer 237 is disposed over the gate structure 230. An interface dielectric layer 272 is disposed over the source/drain contact 226, the CESL 222, the SAC layer 237, and the gate spacer 236. An etch stop layer (ESL) 238 is disposed over the interface dielectric layer 272. In some embodiments, the source/drain contact 226 may include cobalt (Co), nickel (Ni), tungsten (W), molybdenum (Mo), or ruthenium (Ru). A conductive feature 274 is formed in the interface dielectric layer 272 and the ESL 238. In some embodiments, the conductive feature 274 has a smaller bottom surface to interface the source/drain contact 226 and a greater top surface away from the source/drain contact 26. In these embodiments, the conductive feature 274 may improve alignment window or reduce contact resistance. In some instances, the conductive feature 274 includes tungsten (W), molybdenum (Mo), ruthenium (Ru), cobalt (Co), nickel (Ni), copper (Cu), or a combination thereof.

To form the first multi-gate device structure 10, a superlattice structure is deposited over the substrate 202. The substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GalnP), and indium gallium arsenide (InGaAs). The substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

The superlattice structure may include a plurality of channel layers interleaved by a plurality of sacrificial layers. The channel layers and the sacrificial layers may have different semiconductor compositions. In some implementations, the channel layers are formed of silicon (Si) and sacrificial layers 206 are formed of silicon germanium (SiGe). In these implementations, the additional germanium content in the sacrificial layers allow selective removal or recess of the sacrificial layers without substantial damages to the channel layers. The sacrificial layers and the channel layers are deposited alternatingly, one-after-another, to form superlattice structure. The channel layers and the sacrificial layers are deposited one over another using vapor-phase cpitaxy (VPE), ultra-high vacuum chemical vapor deposition (UHV-CVD), molecular beam epitaxy (MBE), and/or other suitable epitaxy deposition processes. The superlattice structure may also be referred to as an cpitaxial stack.

After the deposition of the superlattice structure over the substrate 202, a fin-shaped structure is formed from the superlattice structure and a portion of the substrate 202 using photolithography and etching techniques. After formation of the fin-shaped structures, an isolation feature (not shown) is formed around the fin-shaped structure to separate the fin-shaped structure from an adjacent fin-shaped structure. The isolation feature may also be referred to as a shallow trench isolation (STI) feature. In an example process, a dielectric material for the isolation feature is deposited over the substrate 202, including the fin-shaped structure, using CVD, subatmospheric CVD (SACVD), flowable CVD, spin-on coating, and/or other suitable process. Then the deposited dielectric material is planarized and recessed to form the isolation feature. After the recessing, the fin-shaped structure rises above the isolation feature. The dielectric material for the isolation feature may include silicon oxide, silicon oxynitride, silicon oxycarbonitride, fluorine-doped silicate glass (FSG), a low-k dielectric, combinations thereof, and/or other suitable materials. After formation of the STI feature, a dummy gate stack is formed over the channel regions. The dummy gate stack includes a dummy gate dielectric layer and a dummy gate electrode. The dummy gate dielectric layer may include silicon oxide and the dummy gate electrode may include polysilicon (poly-Si). The gate spacer 236 is then deposited over the dummy gate structure. The gate spacer 236 may include silicon oxycarbonitride or silicon nitride. After deposition of the gate spacer 236, a dry etch process is performed to directionally etch the source/drain regions 210SD of the active region to form a source/drain recess that may partially extend into the base fin formed from the substrate 202. The sacrificial layers exposed in the source/drain recess are then selectively and partially recessed to form inner spacer recesses between channel layers. Inner spacer features 228 are then formed in the inner spacer recesses. In some embodiments, the inner spacer features 228 may include silicon oxycarbonitride, silicon nitride, or silicon oxynitride. After the formation of the inner spacer features 228, more than one epitaxial layers are epitaxially deposited over the source/drain recesses to form the bottom source/drain features 220. The more than one epitaxial layers may include a first epitaxial layer interfacing end walls of the channel layers and a second epitaxial layer spaced apart from the channel layers by the first epitaxial layer. The bottom source/drain feature 220 may be n-type or p-type. When the bottom source/drain feature 220 is n-type, it may include silicon (Si) and an n-type dopant, such as phosphorus (P) or arsenic (As). When the bottom source/drain feature 220 is p-type, it may include silicon germanium (SiGe) and a p-type dopant, such boron (B). In the depicted embodiment, the bottom source/drain feature 220 include silicon germanium (SiGe) and a p-type dopant. After formation of the bottom source/drain features 220, the CESL 222 and an interlayer dielectric (ILD) layer are deposited over the bottom source/drain features 220 using atomic layer deposition (ALD) or chemical vapor deposition (CVD). In some embodiments, the CESL 222 may include silicon nitride or aluminum nitride and the ILD layer may include silicon oxide.

After formation of the CESL 222 and the ILD layer, a planarization process is performed to expose the dummy gate stack. The dummy gate stack is then removed using selective etching to expose the channel layers and sacrificial layers in the channel regions 210C. After the removal of the dummy gate stacks, sidewalls of the channel layers and sacrificial layers in the channel regions 210C are exposed. Thereafter, the sacrificial layers in the channel regions 210C are selectively removed to release the channel layers as the nanostructures 2080. The selective removal of the sacrificial layers may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH. With the nanostructures 2080 released, the gate structure 230 is deposited to wrap around each of the nanostructures 2080. The gate structure 230 includes an interfacial layer 231, a gate dielectric layer 232 over the interfacial layer 231, and a gate electrode 234 over the gate dielectric layer 232. In some embodiments, the interfacial layer includes silicon oxide and may be formed in a pre-clean process. An example pre-clean process may include use of a solution of ammonia, hydrogen peroxide and water and/or a solution of hydrochloric acid, hydrogen peroxide and water. The gate dielectric layer 232 is then deposited over the interfacial layer using ALD, CVD, and/or other suitable methods. The gate dielectric layer 232 is formed of high-k dielectric materials. As used and described herein, high-k dielectric materials include dielectric materials having a high dielectric constant, for example, greater than that of thermal silicon oxide (˜3.9). In some embodiments, the gate dielectric layer 232 may include hafnium oxide. Alternatively, the gate dielectric layer 232 may include other high-k dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), or a combination thereof. In some embodiments, a dielectric constant of the gate dielectric layer 232 is greater than a dielectric constant of the gate spacer 236, the inner spacer feature 228, or the CESL 222.

After the deposition of the gate dielectric layer 232, a work function layer may be deposited over the gate dielectric layer 232. The work function layer may be n-type or p-type. By way of example, the p-type work function layer may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer may include titanium (Ti), aluminum (Al), silver (Ag), manganese (Mn), zirconium (Zr), titanium aluminum (TiAl), titanium aluminum carbide (TiAIC), tantalum carbide (TaC), tantalum carbonitride (TaCN), tantalum silicide nitride (TaSiN), tantalum aluminum (TaAl), tantalum aluminum carbide (TaAIC), titanium aluminum nitride (TiAIN), other n-type work function material, or combinations thereof. The gate structure 230 may also include a metal fill to reduce contact resistance. In some instance, the metal fill includes tungsten (W). The work function layer and the metal fill may be collectively referred to as the gate electrode 234. In one embodiment, the gate structure 230 may include p-type work function layer. Because both n-type work function layer and the p-type work function layer may include a titanium-containing material, the gate structure 230 may be said to include a titanium-based material.

After the formation of the gate structure 230, the gate structure 230 is recessed to form a gate-top recess. The SAC layer 237 is then deposited over the gate top recess. In some embodiments, the SAC layer 237 may include silicon nitride or silicon oxycarbonitride. A planarization is performed to form a planar top surface. The interface dielectric layer 272 is deposited over the planar top surface. The interface dielectric layer 272 may include silicon oxide or an oxide-containing dielectric material. The ESL 238 is then deposited over the interface dielectric layer 272. The ESL 238 may include aluminum nitride, aluminum oxide, silicon nitride, silicon oxycarbonitride, or a combination thereof.

Referring to FIGS. 1, 2 and 3, method 100 includes a block 104 where a high-kappa dielectric layer 240 is formed over the first multi-gate device structure 10. In some embodiments, the high-kappa dielectric layer 240 is formed over the first multi-gate device structure 10 using a film transfer process. In an example process, the high-kappa dielectric layer 240 is first deposited on a uniform surface of a growth substrate 212. The growth substrate 212 may include silicon, silicon carbide, sapphire, or magnesium oxide. The high-kappa dielectric layer 240 is deposited on the growth substrate 212 using CVD, physical vapor deposition (PVD), or physical vapor transport (PVT). The high-kappa dielectric layer 240 has a thermal conductivity greater than the thermal conductivity of any other dielectric features in the first multi-gate device structure 10, including the inner spacer features 228, the gate spacers 236, the interfacial layer 231, the gate dielectric layer 232, the CESL 222, and the SAC layer 237. In the depicted embodiments, the high-kappa dielectric layer 240 has a thermal conductivity between about 300 W/mk and about 2500 W/mk. In some embodiments, the high-kappa dielectric layer 240 may include diamond, boron nitride (BN), aluminum nitride (AlN), aluminum boron nitride (AIBN), or boron arsenide (BAs). When the high-kappa dielectric layer 240 includes diamond, it may be deposited over the growth substrate 212 using CVD. When the high-kappa dielectric layer 240 includes cubic boron nitride (cBN), it may be deposited over the growth substrate 212 using PVD. When the high-kappa dielectric layer 240 includes hexagonal boron nitride (hBN), it may be deposited over the growth substrate 212 using CVD or PVD. When the high-kappa dielectric layer 240 includes aluminum nitride, it may be deposited over the growth substrate 212 using PVD. When the high-kappa dielectric layer 240 includes aluminum boron nitride, it may be deposited over the growth substrate 212 using CVD or PVT. When the high-kappa dielectric layer 240 includes boron arsenide, it may be deposited over the growth substrate 212 using CVD or PVD. In one embodiment, the high-kappa dielectric layer 240 may include diamond, boron nitride, or aluminum nitride as deposition of these materials require a temperature lower than 500° C. In some embodiments, the high-kappa dielectric layer 240 has a thickness between 5 nm and about 100 nm.

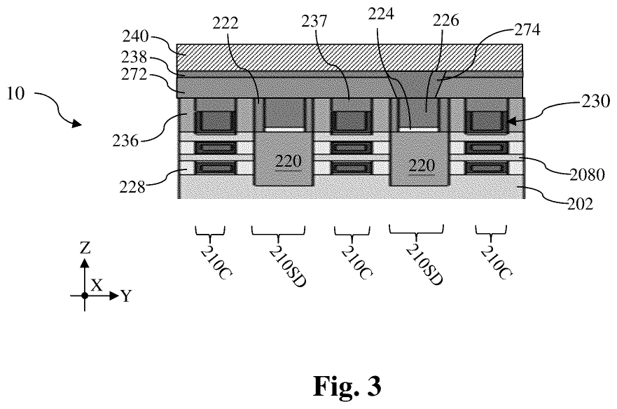

As shown in FIG. 3, after the high-kappa dielectric layer 240 is formed on the growth substrate 212, the high-kappa dielectric layer 240 is bonded over the first multi-gate device structure 10. To bond the high-kappa dielectric layer 240 and the ESL 238, their exposed surfaces are first treated with a nitrogen (N₂) plasma, an oxygen (O₂) plasma, or an argon (Ar) plasma to introduce surface hydroxyl groups, amine groups, or other dangling bonds. After the treatment, surfaces of the high-kappa dielectric layer 240 and the ESL 238 may be cleaned with deionized (DI) water. In some alternative embodiments, before the plasma treatment, the high-kappa dielectric layer 240 and the ESL 238 may be optionally cleaned to remove organic and metallic contaminants. In an example process, a mixture of ammonium hydroxide and hydrogen peroxide (SC1) and/or a mixture of hydrochloric acid and hydrogen peroxide (SC2) may be used to clean surfaces of the bonding surfaces. The mixture of ammonium hydroxide and hydrogen peroxide (SC1) may remove organic contaminants. The mixture of hydrochloric acid and hydrogen peroxide (SC2) may remove metallic contaminants. After the plasma treatment, the high-kappa dielectric layer 240 is brought to direct contact with the ESL 238. An anneal is performed to promote the covalent bonding of the high-kappa dielectric layer 240 to the ESL 238. The bonding process may be performed at a temperature between about 0° C. and about 400° C. After the high-kappa dielectric layer 240 is bonded to the first multi-gate device structure 10, the growth substrate 212 may be selectively removed using a chemical mechanical polishing (CMP) process, a wet etch process, a dry etch process, or a debonding process.

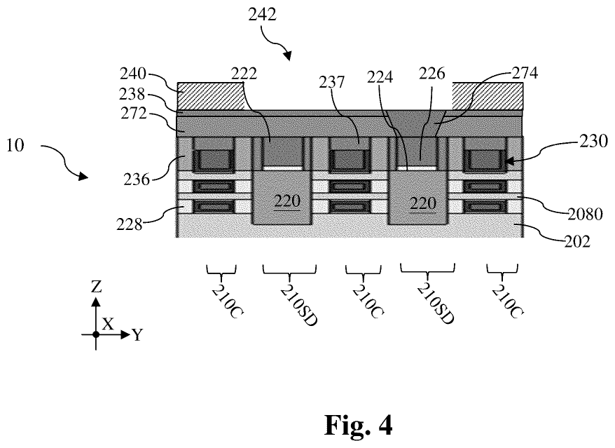

Referring to FIGS. 1 and 4, method 100 includes a block 106 where the high-kappa dielectric layer 240 is patterned to form a contact opening 242. At block 106, photolithography and etch processes are used to pattern the high-kappa dielectric layer 240. In an example process, a hard mask layer is deposited over the high-kappa dielectric layer 240 and a photoresist layer is deposited over the hard mask layer. The photoresist layer is then patterned using photolithography techniques. The hard mask layer and the high-kappa dielectric layer 240 are then etched using the patterned photoresist layer as an etch mask. The etching at block 106 may include a dry etch, a wet etch, or a combination thereof to form the contact opening 242 in the high-kappa dielectric layer 240. For example, when the high-kappa dielectric layer 240 includes diamond, the dry etch may include use of argon, oxygen, chlorine, or boron trichloride and the wet etch may include use of a molten form of potassium nitrate (KNO₃). When the high-kappa dielectric layer 240 includes hexagonal boron nitride, the dry etch may include use of argon, hydrogen, oxygen, carbon tetrafluoride (CF₄). When the high-kappa dielectric layer 240 includes cubic boron nitride, the dry etch may include use of argon or methane and the wet etch may include use of a sodium hydroxide solution or sulfuric acid. When the high-kappa dielectric layer 240 includes aluminum nitride, the dry etch may include use of chlorine, argon, trifluoromethane, sulfur hexafluoride, or boron trichloride and the wet etch may include use of a potassium hydroxide solution, phosphoric acid, tetramethylammonium hydroxide (TMAH), or hydrofluoric acid. When the high-kappa dielectric layer 240 includes boron arsenide, the wet etch may include use of a molten form of potassium hydroxide (KOH). During the etching, the photoresist layer is selectively removed by ashing or selective etching. After the formation of the contact opening 242, the hard mask layer is removed by etching. In the depicted embodiment, the top surface of the contact feature 274 and the ESL 238 are exposed in the contact opening 242.

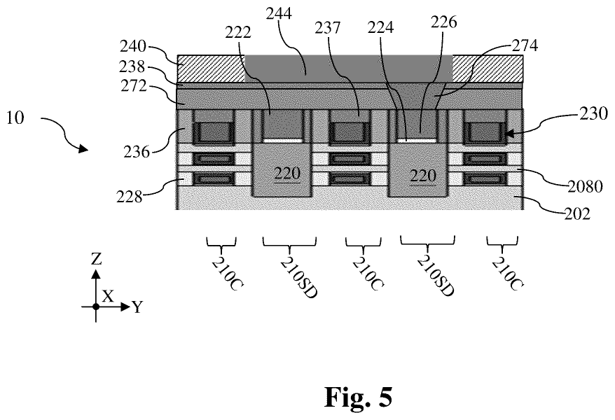

Referring to FIGS. 1 and 5, method 100 includes a block 108 where a contact feature 244 is formed into the contact opening 242. At block 108, a metal fill layer is deposited over the contact opening 242 using PVD or CVD. In some embodiments, the metal fill layer may include tungsten (W), molybdenum (Mo), ruthenium (Ru), cobalt (Co), nickel (Ni), copper (Cu), or a combination thereof. After deposition of the metal fill layer, a planarization process, such as a CMP process, is performed to form the contact feature 244 in the high-kappa dielectric layer 240. In the depicted embodiment, the contact feature 244 is physically and electrically coupled to the contact feature 274.

Referring to FIGS. 1, 6 and 7, method 100 includes a block 110 where a superlattice structure 250 is bonded over the contact feature 244 and the high-kappa dielectric layer 240. In some embodiments, the superlattice structure 250 includes a plurality channel layers 208 interleaved by a plurality of sacrificial layers 206. It is noted that the superlattice structure 250 may be similar to the superlattice structure from which the first multi-gate device structure 10 is formed. In the depicted embodiment, the bottommost layer of the superlattice structure 250 is a sacrificial layer 206 and the topmost layer of the superlattice structure 250 is a top channel layer 208T, which is thicker than the rest of the channel layers 208 to endure subsequent processes. In some embodiments, the channel layers 208 (including the top channel layer 208T) include silicon (Si) and the sacrificial layers 206 include silicon germanium (SiGe). The superlattice structure 250 may be formed using vapor-phase epitaxy (VPE), ultra-high vacuum chemical vapor deposition (UHV-CVD), molecular beam epitaxy (MBE), and/or other suitable epitaxy deposition processes. To bond the superlattice structure 250 to the high-kappa dielectric layer 240 and the contact feature 244, their exposed surfaces are first treated with a nitrogen (N₂) plasma, an oxygen (O₂) plasma, or an argon (Ar) plasma to introduce surface hydroxyl groups, amine groups, or other dangling bonds. After the treatment, the bonding surfaces may be cleaned with deionized (DI) water. In some alternative embodiments, before the plasma treatment, the superlattice structure 250, the high-kappa dielectric layer 240 and the contact feature 244 may be optionally cleaned to remove organic and metallic contaminants. In an example process, a mixture of ammonium hydroxide and hydrogen peroxide (SC1) and/or a mixture of hydrochloric acid and hydrogen peroxide (SC2) may be used to clean surfaces of the superlattice structure 250, the high-kappa dielectric layer 240 and the contact feature 244. The mixture of ammonium hydroxide and hydrogen peroxide (SC1) may remove organic contaminants. The mixture of hydrochloric acid and hydrogen peroxide (SC2) may remove metallic contaminants. After the plasma treatment, the superlattice structure 250 is brought to direct contact with the high-kappa dielectric layer 240 and the contact feature 244. An anneal is performed to promote the covalent force bonding of the superlattice structure 250 to the high-kappa dielectric layer 240.

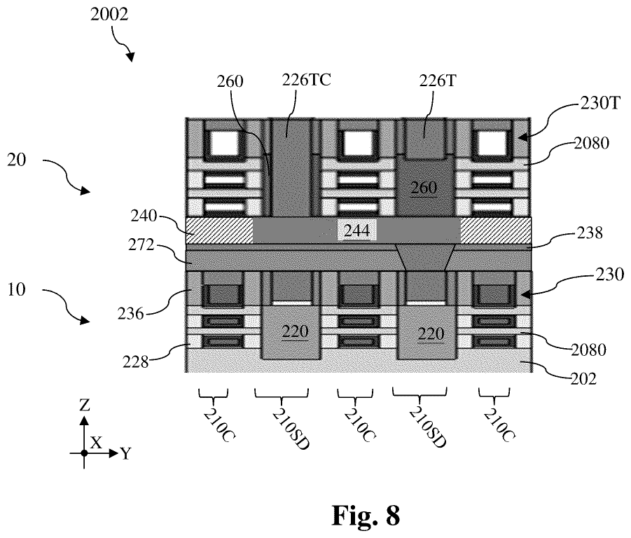

Referring to FIGS. 1 and 8, method 100 includes a block 112 where a second multi-gate device structure 20 is formed from the superlattice structure 250. At block 112, processes used to form the first multi-gate device structure 10 may be used to form the second multi-gate device structure 20. For brevity, a detailed process for forming the second multi-gate device structure 20 is omitted. Like the first multi-gate device structure 10, the second multi-gate device structure 20 includes nanostructures 2080. The nanostructures 2080 in the second multi-gate device structure 20 extend between two top source/drain features 260. The top source/drain feature 260 may be n-type or p-type. When the top source/drain feature 260 is n-type, it may include silicon (Si) and an n-type dopant, such as phosphorus (P) or arsenic (As). When the top source/drain feature 260 is p-type, it may include silicon germanium (SiGe) and a p-type dopant, such boron (B). In the depicted embodiment, the top source/drain feature 260 include silicon (Si) and an n-type dopant. The second multi-gate device structure 20 includes a top gate structure 230T that wraps around each of the nanostructures 2080. The second multi-gate device structure 20 may include different contact features. In the depicted embodiments, a source/drain contact 226 is disposed over and interfaces a top source/drain feature 260 and a through source/drain contact 226TC extends through another top source/drain feature 260 to contact the contact feature 244. In some embodiments, the source/drain contact 226 and the through source/drain contact 226TC may include cobalt (Co), nickel (Ni), tungsten (W), molybdenum (Mo), or ruthenium (Ru). The first multi-gate device structure 10, second multi-gate device structure 20, the high-kappa dielectric layer 240, and the contact feature 244 shown in FIG. 8 may be collectively referred to as a first stacked device structure 2002.

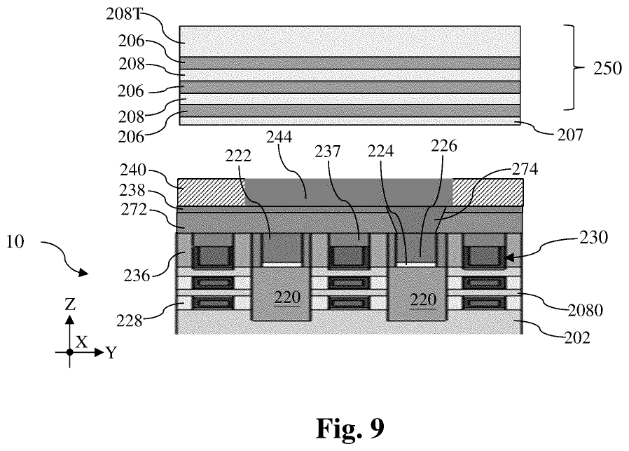

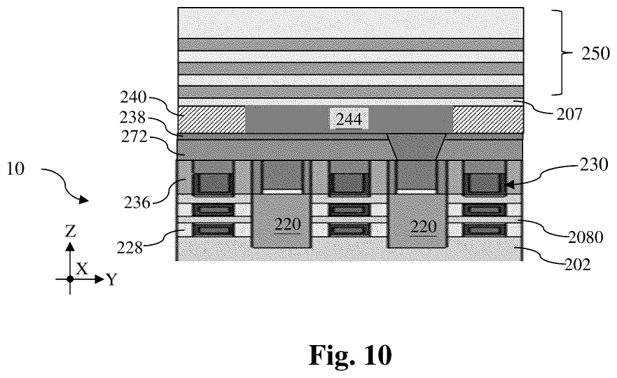

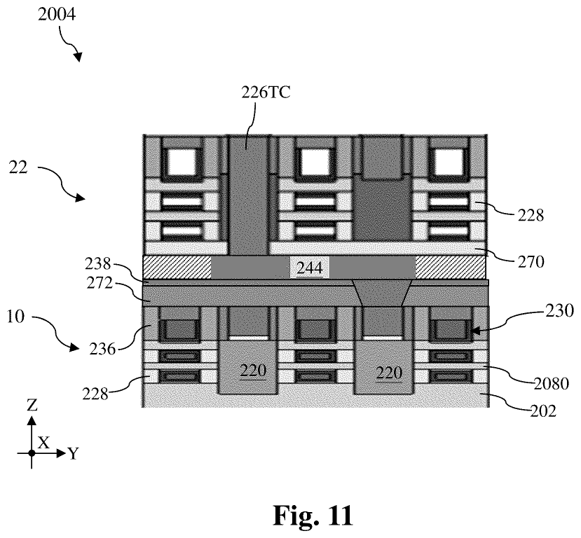

FIGS. 9-11 illustrates an alternative embodiment when steps in method 100 are followed. In some embodiments presented in FIG. 9, a dielectric layer 207 is formed over a surface of the superlattice structure 250 before the bonding of the superlattice structure 250 to the first multi-gate device structure 10. The dielectric layer 207 functions to aid the bonding process and may also be referred to as a bonding dielectric layer 207. Depending on the high-kappa dielectric layer 240, the dielectric layer 207 may include silicon nitride, silicon oxide, silicon carbide, silicon oxynitride, silicon oxycarbide, silicon oxycarbonitride, boron oxide, boron oxynitride, aluminum oxide, aluminum oxynitride, arsenic oxide, or arsenic oxynitride. To further improve bonding strength with the high-kappa dielectric layer 240, the dielectric layer 207 may further be doped with germanium (Ge), boron (B), aluminum (Al), arsenic (As), or a combination thereof. With the dopants, the dielectric layer 207 may include boron oxide, silicon boride, silicon boron oxide, silicon boron carbide, silicon boron oxycarbide, silicon boron nitride, silicon boron oxynitride, silicon boron oxycarbonitride, silicon germanium boride, silicon germanium boron oxide, silicon germanium boron carbide, silicon germanium boron oxycarbide, silicon germanium boron nitride, silicon germanium boron oxynitride, silicon germanium boron oxycarbonitride, aluminum oxide, silicon aluminum oxide, silicon aluminum carbide, silicon aluminum nitride, silicon aluminum oxynitride, silicon aluminum oxycarbide, silicon aluminum carbonitride, silicon aluminum oxycarbonitride, aluminum boride, aluminum boron oxide, aluminum boron carbide, aluminum boron oxycarbide, aluminum boron nitride, aluminum boron oxynitride, aluminum boron oxycarbonitride, silicon aluminum boride, silicon aluminum boron oxide, silicon aluminum boron carbide, silicon aluminum boron oxycarbide, silicon aluminum boron nitride, silicon aluminum boron oxynitride, silicon aluminum boron oxycarbonitride, arsenic oxide, arsenic nitride, arsenic carbide, arsenic oxynitride, arsenic oxycarbide, arsenic carbonitride, arsenic oxycarbonitride, silicon arsenide, silicon arsenic oxide, silicon arsenic carbide, silicon arsenic oxynitride, silicon arsenic oxycarbide, silicon arsenic carbonitride, silicon arsenic oxycarbonitride, silicon boron arsenide, silicon boron arsenic oxide, silicon boron arsenic carbide, silicon boron arsenic oxynitride, silicon boron arsenic oxycarbide, silicon boron arsenic carbonitride, silicon boron arsenic oxycarbonitride. The dielectric layer 207 may be deposited over the superlattice structure 250 using thermal oxidation or CVD. At block 110 of method 100, as illustrated in FIG. 10, the superlattice structure 250 is bonded to the high-kappa dielectric layer 240 and the contact feature 244 by way of the dielectric layer 207 using a bonding process similar to what is described above with respect to the operations at block 110. The superlattice structure 250 then undergoes operations at block 112 to form the second stacked device structure 2004 shown in FIG. 11. Compared to the second multi-gate device structure 20 shown in FIG. 9, a second multi-gate device structure 22 in FIG. 11 further includes a bottom dielectric layer 270. In some instances, the bottom dielectric layer 270 may have a composition similar to that of the inner spacer feature 228. In both the first stacked device structure 2002 and the second stacked device structure 2004, a back side of the second multi-gate device structure 20 (or 22 in FIG. 11) is bonded to a front side of the first multi-gate device structure 10. This configuration may be referred to as a face-to-back scheme.

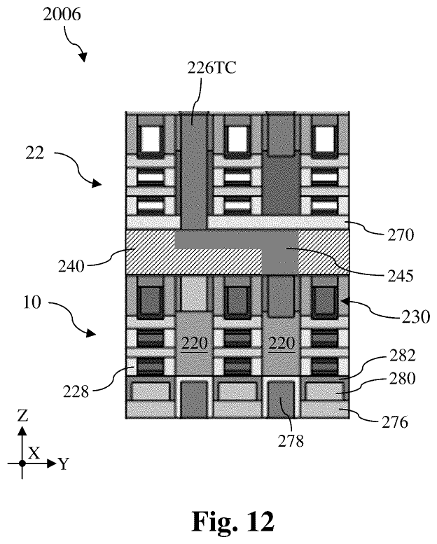

FIGS. 12-22 illustrate various example device structures that may be formed using method 100. FIG. 12 illustrates a third stacked device structure 2006. The third stacked device structure 2006 is constructed according to the face-to-back scheme as a back side of the second multi-gate device structure 22 is bonded to a front side of the first multi-gate device structure 10 by way of the high-kappa dielectric layer 240. A two-tier contact feature 245 is disposed in the high-kappa dielectric layer 240. The two-tier contact feature 245 includes a via to interface the first multi-gate device structure 10 and a metal line to interface the second multi-gate device structure 22. The first multi-gate device structure 10 includes backside contact features 278 that interface bottom surfaces of the bottom source/drain features 220. The third stacked device structure 2006 further includes a bottom liner 282 disposed below the gate structure 230, a first bottom ILD layer 280, and a second bottom ILD layer 276. The backside contact features 278 extend through the bottom liner 282, the first bottom ILD layer 280, and the second bottom ILD layer 276. In some embodiments, the bottom liner 282 includes silicon nitride and the first bottom ILD layer 280 and the second bottom ILD layer 276 includes silicon oxide.

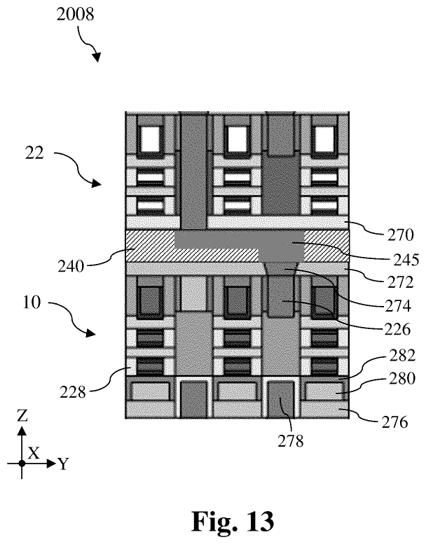

FIG. 13 illustrates a fourth stacked device structure 2008. The fourth stacked device structure 2008 is constructed according to the face-to-back scheme as a back side of the second multi-gate device structure 22 is bonded to a front side of the first multi-gate device structure 10 by way of the high-kappa dielectric layer 240. Compared to the third stacked device structure 2006, the fourth stacked device structure 2008 further includes an interface dielectric layer 272 between the first multi-gate device structure 10 and the high-kappa dielectric layer 240. A conductive feature 274 extends through the interface dielectric layer 272 to connect the source/drain contact 226 to the two-tier contact feature 245. In some embodiments, the interface dielectric layer 272 includes silicon oxide and the conductive feature 274 includes tungsten (W), molybdenum (Mo), ruthenium (Ru), cobalt (Co), nickel (Ni), copper (Cu), or a combination thereof.

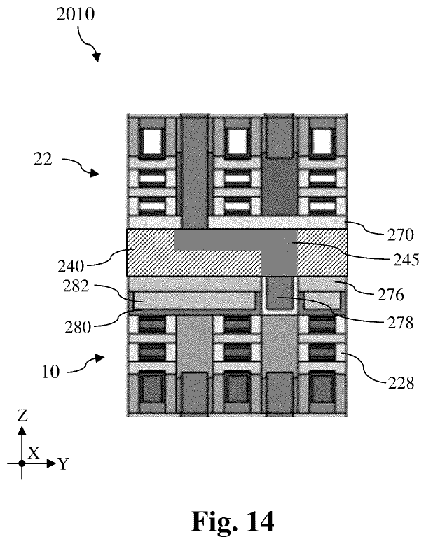

FIG. 14 illustrates a fifth stacked device structure 2010. The fifth stacked device structure 2010 is constructed according to the back-to-back scheme as a back side of the second multi-gate device structure 22 is bonded to a back side of the first multi-gate device structure 10 by way of the high-kappa dielectric layer 240. Compared to the fourth stacked device structure 2008, the high-kappa dielectric layer 240 in the fifth stacked device structure 2010 is bonded to the second bottom ILD layer 276 disposed over a back side of the first multi-gate device structure 10. The backside contact feature 278 extend through the bottom liner 280, the first bottom ILD layer 282, and the second bottom ILD layer 276 to interface the via of the two-tier contact feature 245.

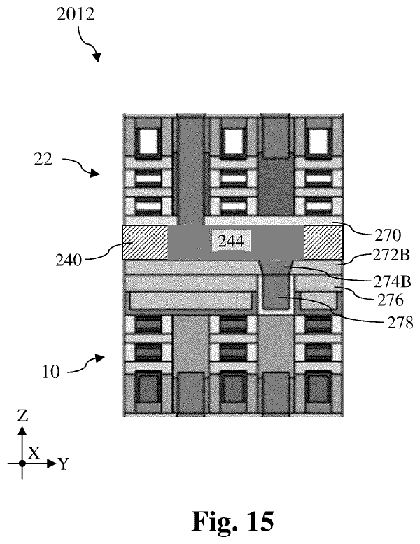

FIG. 15 illustrates a sixth stacked device structure 2012. The sixth stacked device structure 2012 is constructed according to the back-to-back scheme as a back side of the second multi-gate device structure 22 is bonded to a back side of the first multi-gate device structure 10 by way of the high-kappa dielectric layer 240. Compared to the fifth stacked device structure 2010, the high-kappa dielectric layer 240 in the sixth stacked device structure 2012 is bonded to backside interface dielectric layer 272B disposed over a back side of the first multi-gate device structure 10. A backside conductive feature 274B extends through the backside interface dielectric layer 272B to connect the backside contact feature 278 to the contact feature 244. In some embodiments, the backside interface dielectric layer 272B includes silicon oxide and the conductive feature 274 includes tungsten (W), molybdenum (Mo), ruthenium (Ru), cobalt (Co), nickel (Ni), copper (Cu), or a combination thereof.

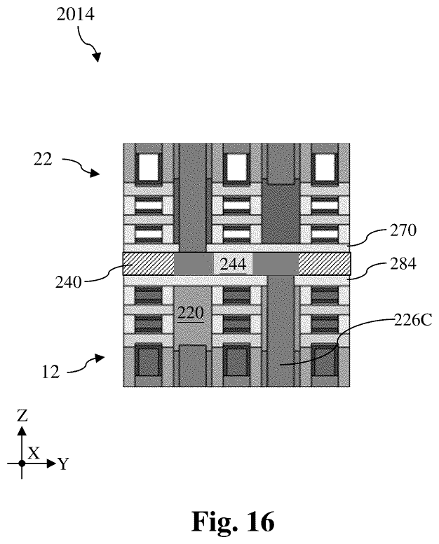

FIG. 16 illustrates a seventh stacked device structure 2014. The seventh stacked device structure 2014 is constructed according to the back-to-back scheme as a back side of the second multi-gate device structure 22 is bonded to a back side of a first multi-gate device structure 12 by way of the high-kappa dielectric layer 240. Compared to the fifth stacked device structure 2010, the first multi-gate device structure 12 in the seventh stacked device structure 2014 does not include the bottom liner 280, the first bottom ILD layer 282, and the second bottom ILD layer 276 shown in FIG. 14. Instead, the first multi-gate device structure 12 in the seventh stacked device structure 2014 includes a bottom dielectric layer 284 to interface bottom surfaces of the bottom source/drain features 220 and the gate structure 230. A bottom through source/drain contact 226C extends through the bottom source/drain feature 220 and the bottom dielectric layer 284 to interface the contact feature 244.

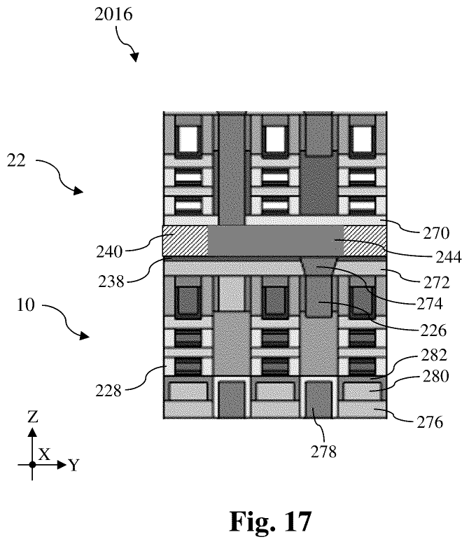

FIG. 17 illustrates an eighth stack device structure 2016. The eighth stacked device structure 2016 is constructed according to the face-to-back scheme as a back side of the second multi-gate device structure 22 is bonded to a front side of the first multi-gate device structure 10 by way of the high-kappa dielectric layer 240. Compared to the fourth stacked device structure 2008, the eighth stacked device structure 2016 includes a single-tier contact feature 244 and an additional ESL 238 between the interface dielectric layer 272 and the high-kappa dielectric layer 240. A conductive feature 274 extends through both the interface dielectric layer 272 and the ESL to connect the source/drain contact 226 to the contact feature 244.

FIG. 18 illustrates a ninth stack device structure 2018. The ninth stacked device structure 2018 is constructed according to the face-to-back scheme as a back side of the second multi-gate device structure 22 is bonded to a front side of the first multi-gate device structure 10 by way of the high-kappa dielectric layer 240. Compared to the eighth stacked device structure 2016, the ninth stacked device structure 2018 further includes an additional bottom dielectric layer 271 between the bottom dielectric layer 270 and the high-kappa dielectric layer 240. The additional bottom dielectric layer 271 may have a composition similar to that of the bottom dielectric layer 270. In some embodiments, the additional bottom dielectric layer 271 functions to apply additional stress to counter wafer warpage or to provide better adhesion to the high-kappa dielectric layer 240.

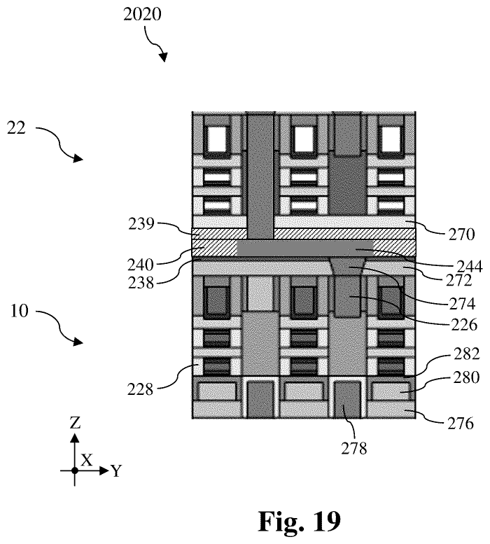

FIG. 19 illustrates a tenth stack device structure 2020. The tenth stacked device structure 2020 is constructed according to the face-to-back scheme as a back side of the second multi-gate device structure 22 is bonded to a front side of the first multi-gate device structure 10 by way of the high-kappa dielectric layer 240. Compared to the ninth stacked device structure 2018, the tenth stacked device structure 2020 includes a bottom high-kappa dielectric layer 239 in place of the additional bottom dielectric layer 271 in the ninth stacked device structure 2018 in FIG. 18. The bottom high-kappa dielectric layer 239 may have a composition similar to that of the high-kappa dielectric layer 240. In some embodiments, the bottom high-kappa dielectric layer 239 helps to provide better adhesion between the bottom dielectric layer 270 and the high-kappa dielectric layer 240 as well as better thermal dissipation.

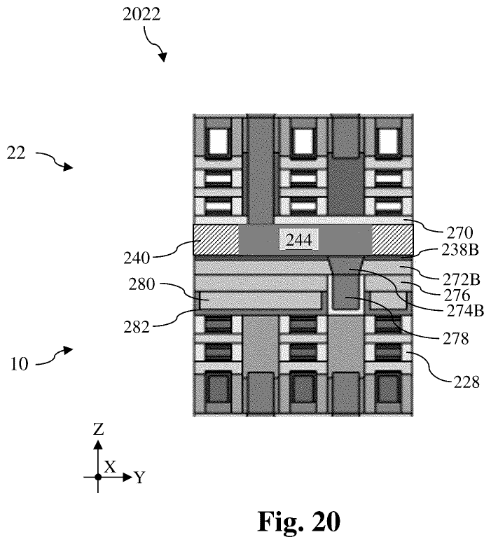

FIG. 20 illustrates an eleventh stack device structure 2022. The eleventh stacked device structure 2022 is constructed according to the back-to-back scheme as a back side of the second multi-gate device structure 22 is bonded to a back side of the first multi-gate device structure 10 by way of the high-kappa dielectric layer 240. Compared to the sixth stacked device structure 2012, the eleventh stacked device structure 2022 further includes a backside etch stop layer (ESL) 238B between the backside interface dielectric layer 272B and the high-kappa dielectric layer 240. The backside conductive feature 274B extends through both the backside interface dielectric layer 272B and the backside ESL 238B to connect the backside contact feature 278 to the contact feature 244. In some embodiments, the backside ESL 238B and the ESL 238 share a similar composition.

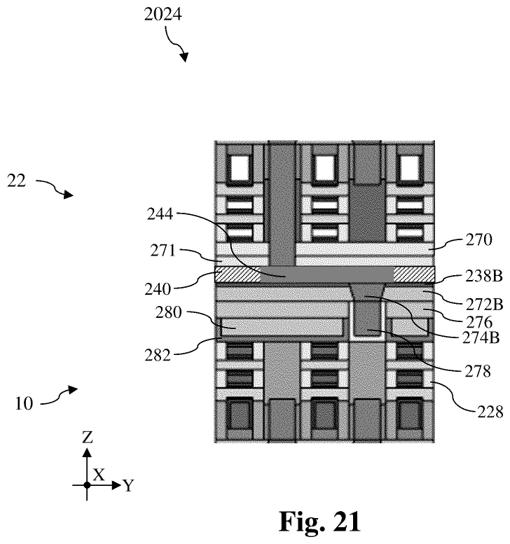

FIG. 21 illustrates a twelfth stack device structure 2024. The twelfth stacked device structure 2024 is constructed according to the back-to-back scheme as a back side of the second multi-gate device structure 22 is bonded to a back side of the first multi-gate device structure 10 by way of the high-kappa dielectric layer 240. Compared to the eleventh stacked device structure 2022, the twelfth stacked device structure 2024 further includes an additional bottom dielectric layer 271 between the bottom dielectric layer 270 and the high-kappa dielectric layer 240. The additional bottom dielectric layer 271 may have a composition similar to that of the bottom dielectric layer 270. In some embodiments, the additional bottom dielectric layer 271 functions to apply additional stress to counter wafer warpage or to provide better adhesion to the high-kappa dielectric layer 240.

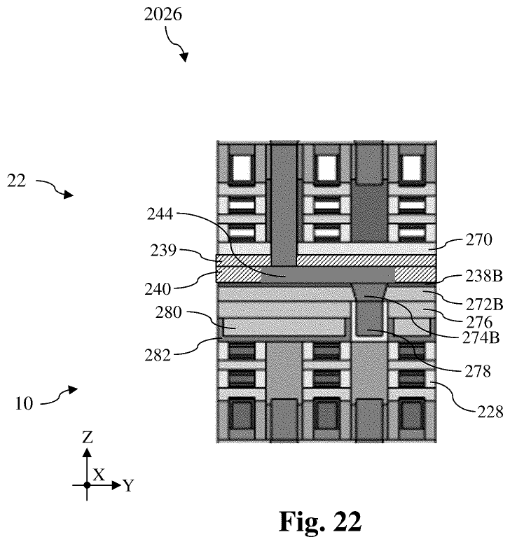

FIG. 22 illustrates a thirteenth stack device structure 2026. The thirteenth stacked device structure 2026 is constructed according to the back-to-back scheme as a back side of the second multi-gate device structure 22 is bonded to a back side of the first multi-gate device structure 10 by way of the high-kappa dielectric layer 240. Compared to the twelfth stacked device structure 2024, the thirteenth stacked device structure 2026 includes a bottom high-kappa dielectric layer 239 in place of the additional bottom dielectric layer 271 in the twelfth stacked device structure 2024 in FIG. 21. The bottom high-kappa dielectric layer 239 may have a composition similar to that of the high-kappa dielectric layer 240. In some embodiments, the bottom high-kappa dielectric layer 239 helps to provide better adhesion between the bottom dielectric layer 270 and the high-kappa dielectric layer 240 as well as better thermal dissipation.

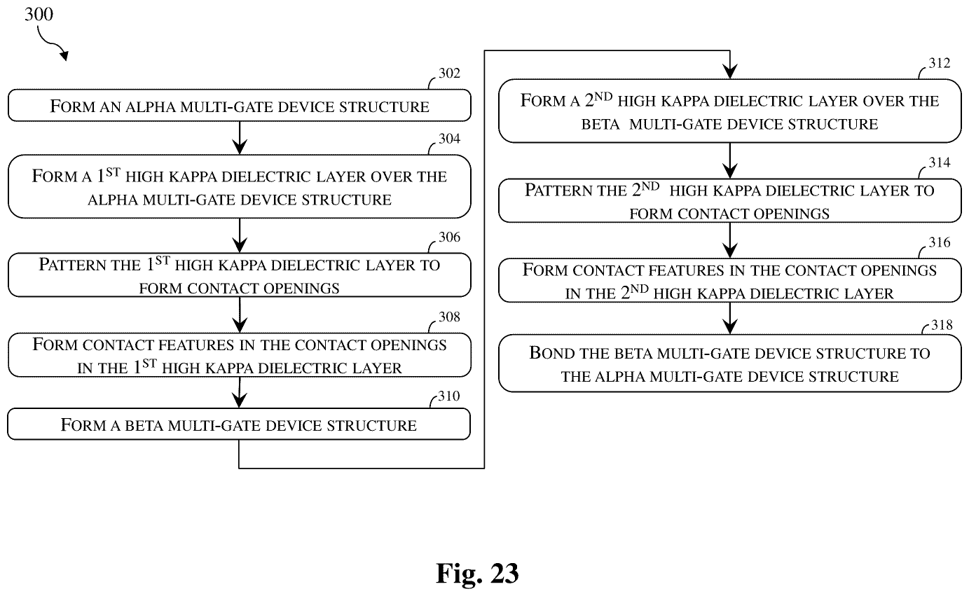

Method 300 in FIG. 23 forms a first high-kappa dielectric layer over a first multi-gate device structure, forms a second high-kappa dielectric layer over a second multi-gate device structure, forms a first contact feature in the first high-kappa dielectric layer and a second contact feature in the second high-kappa dielectric layer, and bonding the first high-kappa dielectric layer to the second high-kappa dielectric layer. Because the first multi-gate device structure and the second multi-gate device structure may be formed separately pursuant to method 300, method 100 may also be referred to a parallel formation scheme.

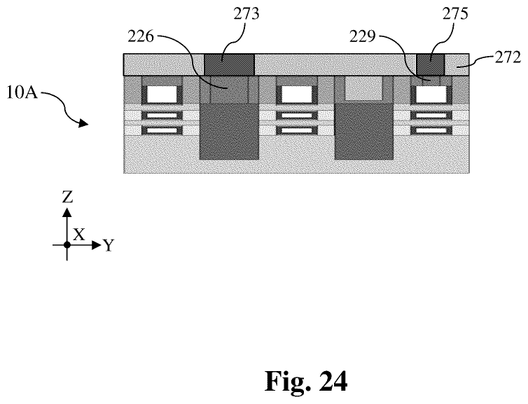

Referring to FIGS. 23 and 24, method 300 includes a block 302 where an alpha multi-gate device structure 10A is formed. Operations at block 302 are similar to those at block 102. Because the operations at block 102 have been described in detail above, a detailed description of operations at block 302 are omitted for brevity. Rather than the first multi-gate device structure 10 formed at block 102, an alpha multi-gate device structure 10A is formed at block 302. As shown in FIG. 18, the alpha multi-gate device structure 10A includes an interface dielectric layer 272. A first conductive feature 273 and a second conductive feature 275 extends through the interface dielectric layer 272 to contact a source/drain contact 226 and a gate contact via 229. respectively. In some embodiments, the interface dielectric layer 272 includes silicon oxide. The first conductive feature 273 and the second conductive feature 275 may include tungsten (W), molybdenum (Mo), ruthenium (Ru), cobalt (Co), nickel (Ni), copper (Cu), or a combination thereof.

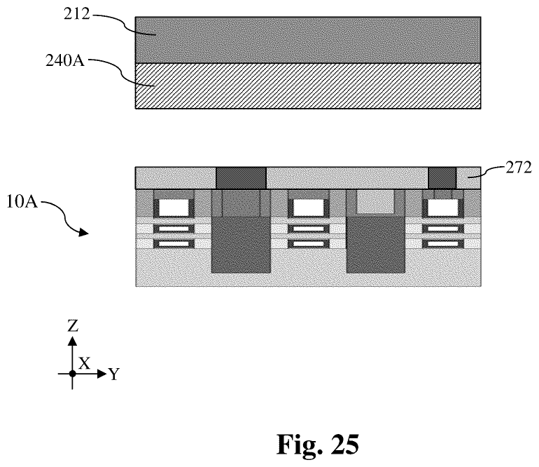

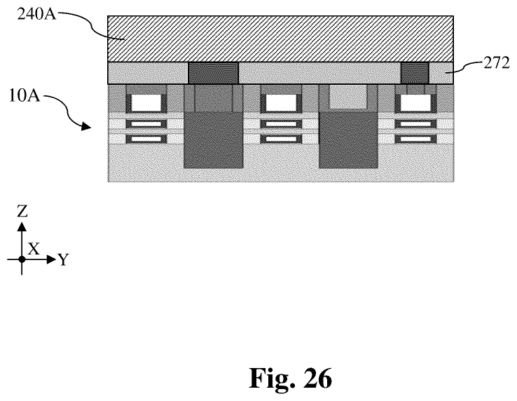

Referring to FIGS. 23, 25 and 26, method 300 includes a block 304 where a first high-kappa dielectric layer 240A is formed over the alpha multi-gate device structure 10A. The formation of the first high-kappa dielectric layer 240A over a front side of the alpha multi-gate device structure 10A is similar to the formation of the high-kappa dielectric layer 240 over the first multi-gate device structure 10 at block 104 of method 100. Because operations at block 104 have been described in detail above, a detailed description of the formation of the first high-kappa dielectric layer 240A over the alpha multi-gate device structure 10A is omitted. In the depicted embodiment, the first high-kappa dielectric layer 240A is first formed over a growth substrate 212, as shown in FIG. 25. The first high-kappa dielectric layer 240A and the growth substrate 212 are then bonded to the alpha multi-gate device structure 10A by way of the interface dielectric layer 272. After the bonding, the growth substrate 212 is selectively removed, leaving the first high-kappa dielectric layer 240A over the alpha multi-gate device structure 10A, as shown in FIG. 26.

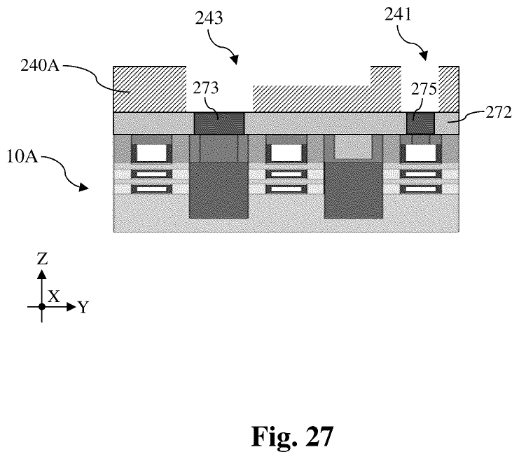

Referring to FIGS. 23 and 27, method 300 includes a block 306 where the first high-kappa dielectric layer 240A is patterned to form contact openings. Operations at block 306 may be similar to those at block 106 described above. For this reason, a detailed description of the operations at block 306 is omitted. At block 306, the first high-kappa dielectric layer 240A is patterned using photolithography and etching processes to form contact openings 243 and 241. In the depicted embodiments, the contact opening 243 exposes the first conductive feature 273 and the contact opening 241 exposes the second conductive feature 275.

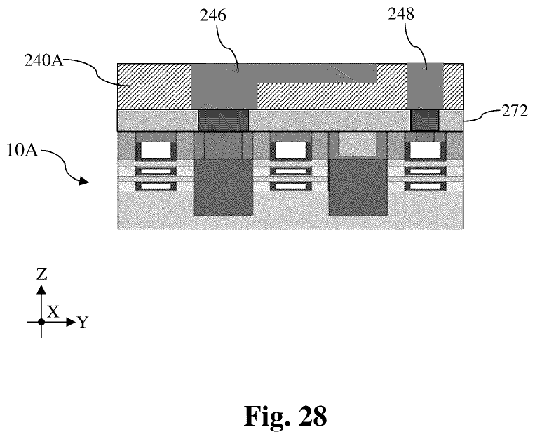

Referring to FIGS. 23 and 28, method 300 includes a block 308 where first contact features are formed in the first contact openings. Operations at block 308 may be similar to those at block 108 described above. For this reason, a detailed description of the operations at block 308 is omitted. At block 308, a metal fill layer is deposited over the contact openings 243 and 241. In some embodiments, the metal fill layer may include tungsten (W), molybdenum (Mo), ruthenium (Ru), cobalt (Co), nickel (Ni), copper (Cu), or a combination thereof. After deposition of the metal fill layer, a planarization process, such as a CMP process, is performed to form a first contact feature 246 and a second contact feature 248 in the first high-kappa dielectric layer 240A.

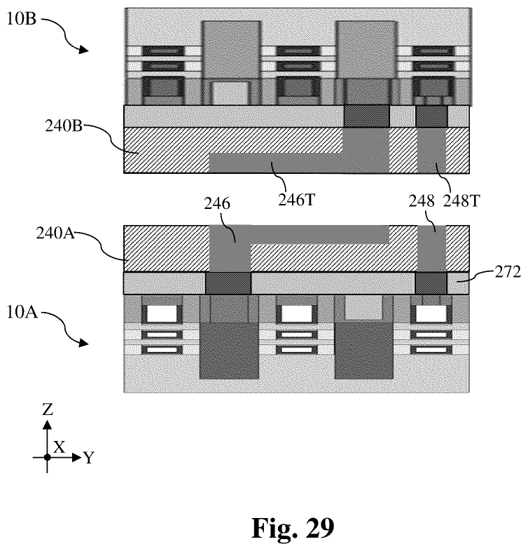

Referring to FIGS. 23 and 29, method 300 includes a block 310 where a beta multi-gate device structure 10B is formed. At block 310, operations at blocks 302, 304 and 306 are repeated before, simultaneously or subsequently to form a beta multi-gate device structure 10B. The beta multi-gate device structure 10B may be of a different conductivity type from the alpha multi-gate device structure 10A. In some embodiments, the alpha multi-gate device structure 10A includes n-type GAA devices and the beta multi-gate device structure 10B includes p-type GAA devices. In some alternative embodiments, the alpha multi-gate device structure 10A includes p-type GAA devices and the beta multi-gate device structure 10B includes n-type GAA devices.

Referring to FIGS. 23 and 29, method 300 includes a block 312 where a second high-kappa dielectric layer 240B is formed over the beta multi-gate device structure 10B. The formation of the second high-kappa dielectric layer 240A over the beta multi-gate device structure 10B is similar to the formation of the high-kappa dielectric layer 240 over the first multi-gate device structure 10 at block 104 of method 100. Because operations at block 104 have been described in detail above, a detailed description of the formation of the second high-kappa dielectric layer 240B over the beta multi-gate device structure 10B is omitted.

Referring to FIGS. 23 and 29, method 300 includes a block 314 where the second high-kappa dielectric layer 240B is patterned to form contact openings. Operations at block 314 are similar to those at block 306. A detailed description of the operations at block 314 is omitted for brevity.

Referring to FIGS. 23 and 29, method 300 includes a block 316 where second contact features are formed in the first contact openings. Operations at block 316 are similar to those at block 308. A detailed description of the operations at block 316 is omitted for brevity. As shown in FIG. 29, a third contact feature 246T and a fourth contact feature 248T are disposed in the second high-kappa dielectric layer 240B.

Referring to FIGS. 23, 29 and 30, method 300 includes a block 318 where the beta multi-gate device structure 10B is bonded to the alpha multi-gate device structure 10A. At block 318, the beta multi-gate device structure 10B is bonded to the alpha multi-gate device structure 10A by bonding the first high-kappa dielectric layer 240A to the second high-kappa dielectric layer 240B. To bond the first high-kappa dielectric layer 240A to the second high-kappa dielectric layer 240B, their exposed surfaces are first treated with a nitrogen (N₂) plasma, an oxygen (O₂) plasma, or an argon (Ar) plasma to introduce surface hydroxyl groups, amine groups, or other dangling bonds. After the treatment, the bonding surfaces may be cleaned with deionized (DI) water. In some alternative embodiments, before the plasma treatment, the first high-kappa dielectric layer 240A and the second high-kappa dielectric layer 240B may be optionally cleaned to remove organic and metallic contaminants. In an example process, a mixture of ammonium hydroxide and hydrogen peroxide (SC1) and/or a mixture of hydrochloric acid and hydrogen peroxide (SC2) may be used to clean surfaces of the first high-kappa dielectric layer 240A, the second high-kappa dielectric layer 240B, and the contact features. The mixture of ammonium hydroxide and hydrogen peroxide (SC1) may remove organic contaminants. The mixture of hydrochloric acid and hydrogen peroxide (SC2) may remove metallic contaminants. After the plasma treatment, the second high-kappa dielectric layer 240B is aligned with and put in direct contact with the first high-kappa dielectric layer 240A. An anneal is performed to promote the covalent bonding of the first high-kappa dielectric layer 240A to the second high-kappa dielectric layer 240B. At conclusion of operations at block 318, a fourteenth stacked device structure 2028 is formed. The fourteenth stacked device structure 2028 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B.

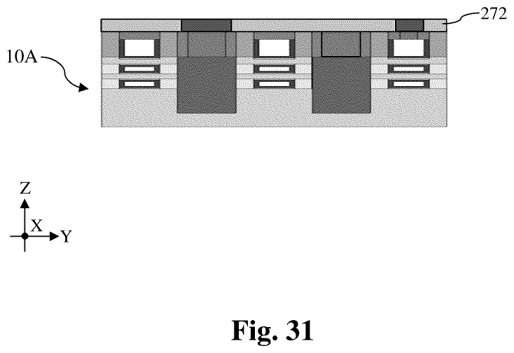

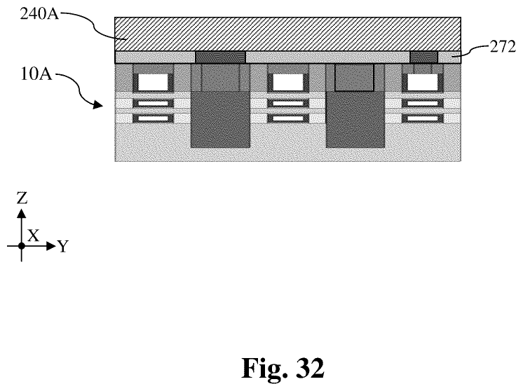

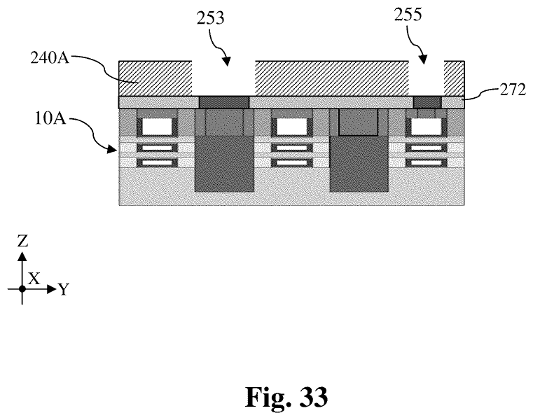

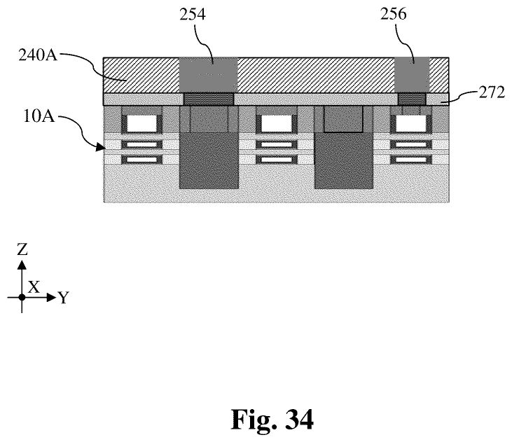

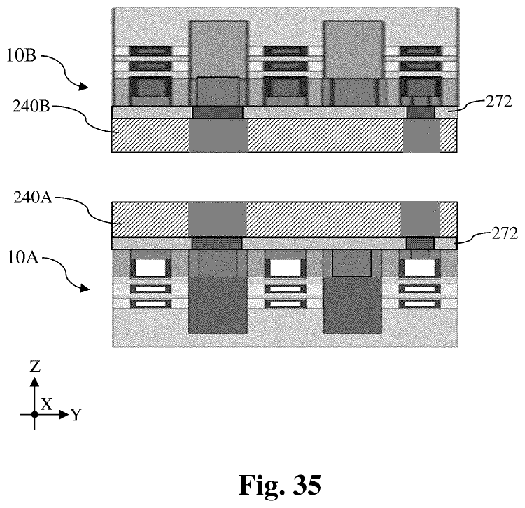

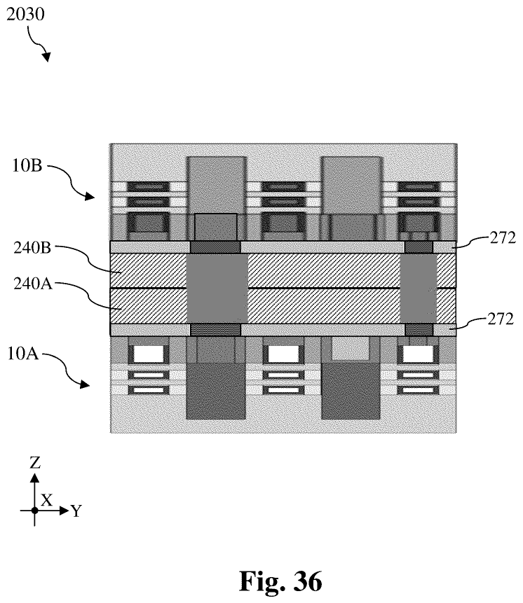

FIGS. 31-36 illustrates an alternative embodiment when steps in method 300 are followed. FIG. 31 illustrates formation of an alpha multi-gate device structure 10A as similarly described at block 302. FIG. 32 illustrates formation of the first high-kappa dielectric layer 240A over the alpha multi-gate device structure 10A. FIG. 33 illustrates formation of contact openings 253 and 255 in the first high-kappa dielectric layer 240A. FIG. 34 illustrates formation of contact features 254 and 256 in the first high-kappa dielectric layer 240A. FIG. 35 illustrates alignment of the alpha multi-gate device structure 10A and the beta multi-gate device structure 10B ahead of the bonding of the two device structures. FIG. 36 illustrates that the alpha multi-gate device structure 10A is bonded to the beta multi-gate device structure 10B by way of the first high-kappa dielectric layer 240A and the second high-kappa dielectric layer 240B. As illustrated in FIG. 36, a fifteenth stacked device structure 2030 is formed. The fifteenth stacked device structure 2030 is different from the fourteenth stacked device structure 2028 in that the fourteenth stacked device structure 2028 includes two-tier contact features such as the first contact feature 246. The fifteenth stacked device structure 2030 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B.

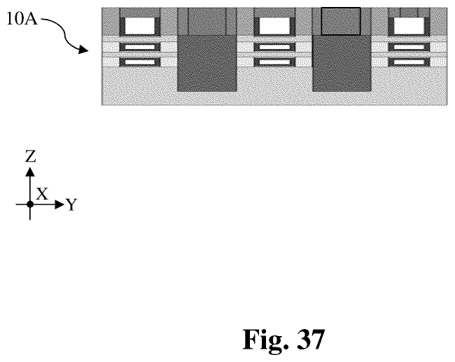

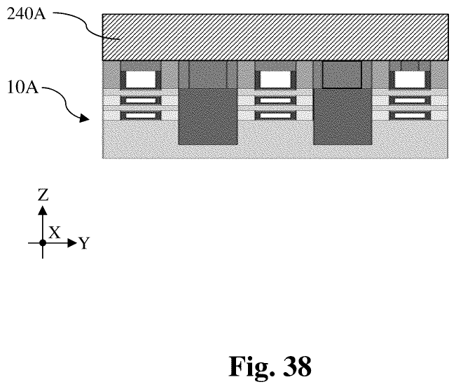

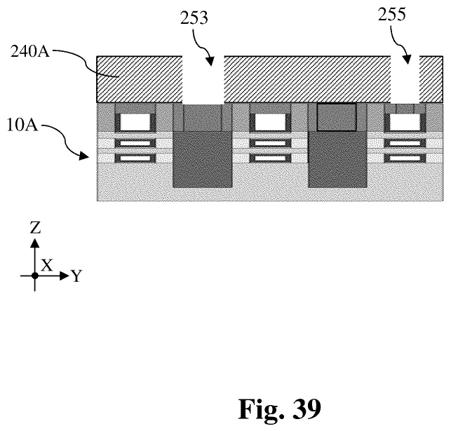

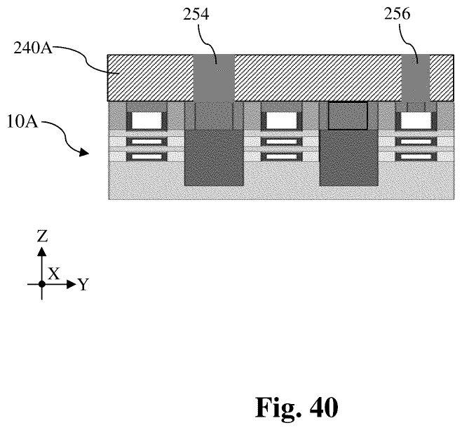

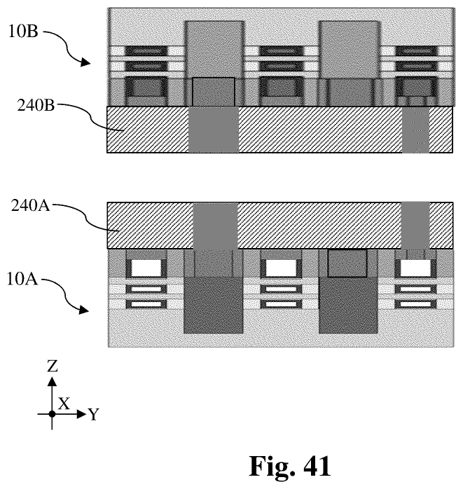

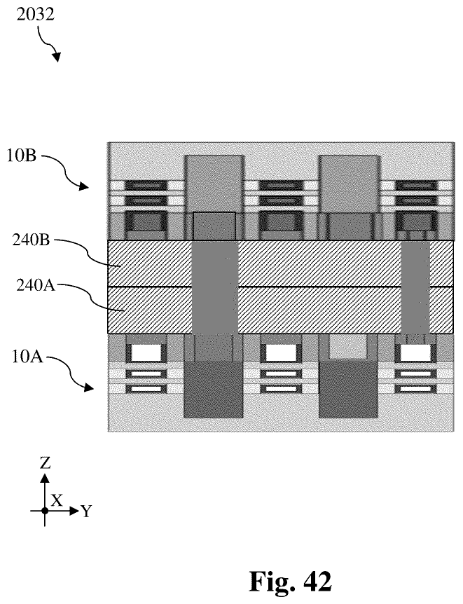

FIGS. 37-42 illustrates another embodiment when steps in method 300 are followed. FIG. 37 illustrates formation of an alpha multi-gate device structure 10A as similarly described at block 302. FIG. 38 illustrates formation of the first high-kappa dielectric layer 240A over the alpha multi-gate device structure 10A without the intervening interface dielectric layer 272. FIG. 39 illustrates formation of contact openings 253 and 255 in the first high-kappa dielectric layer 240A. FIG. 40 illustrates formation of contact features 254 and 256 in the first high-kappa dielectric layer 240A. FIG. 41 illustrates alignment of the alpha multi-gate device structure 10A and the beta multi-gate device structure 10B ahead of the bonding of the two device structures. FIG. 42 illustrates that the alpha multi-gate device structure 10A is bonded to the beta multi-gate device structure 10B by way of the first high-kappa dielectric layer 240A and the second high-kappa dielectric layer 240B. As illustrated in FIG. 42, a sixteenth stacked device structure 2032 is formed. The sixteenth stacked device structure 2032 is different from the fifteenth stacked device structure 2030 in that the sixteenth stacked device structure 2032 does not include the interface dielectric layers 272. The sixteenth stacked device structure 2032 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B.

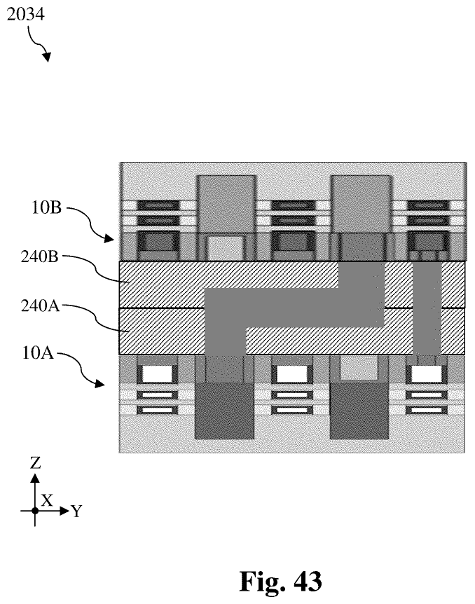

FIGS. 43-54 illustrates alterative structures that may be formed using method 300. FIG. 43 illustrates a seventeenth stacked device structure 2034. The seventeenth stacked device structure 2034 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B.

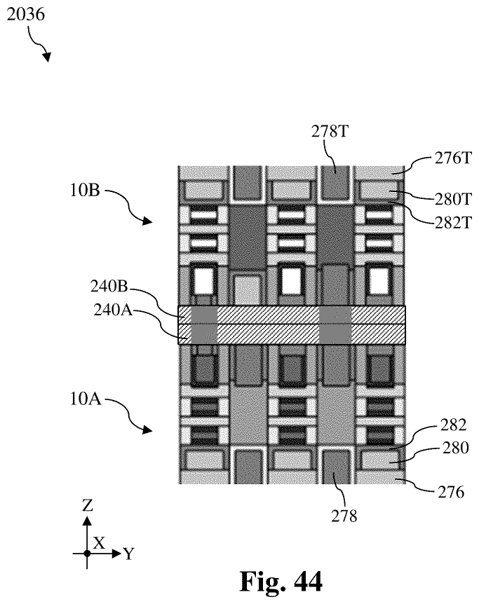

FIG. 44 illustrates an eighteenth stacked device structure 2036. The eighteenth stacked device structure 2036 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B. Both the alpha multi-gate device structure 10A and the beta multi-gate device structure 10B include backside contact features. The alpha multi-gate device structure 10A further includes a bottom liner 282 disposed below the gate structure, a first bottom ILD layer 280 over the bottom liner 282, and a second bottom ILD layer 276 over the bottom liner 282 and the first bottom ILD layer 280. A backside contact features 278 extend through the bottom liner 282, the first bottom ILD layer 280, and the second bottom ILD layer 276. Similarly, the beta multi-gate device structure 10B further includes a bottom liner 282T disposed below the gate structure, a first bottom ILD layer 280T over the bottom liner 282T, and a second bottom ILD layer 276T over the bottom liner 282T and the first bottom ILD layer 280T. A backside contact features 278T extend through the bottom liner 282T, the first bottom ILD layer 280T, and the second bottom ILD layer 276T.

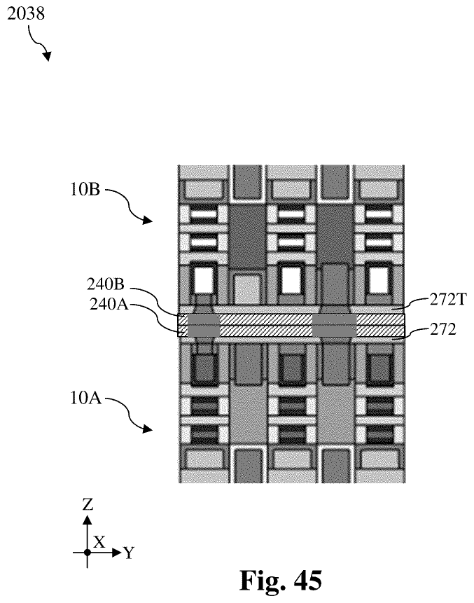

FIG. 45 illustrates a nineteenth stacked device structure 2038. The nineteenth stacked device structure 2038 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B. Compared to the eighteenth stacked device structure 2036, the first high-kappa dielectric layer 240A is bonded to the alpha multi-gate device structure 10A by way of an interface dielectric layer 272 and the second high-kappa dielectric layer 240B is bonded to the beta multi-gate device structure 10B by way of a top interface dielectric layer 272T.

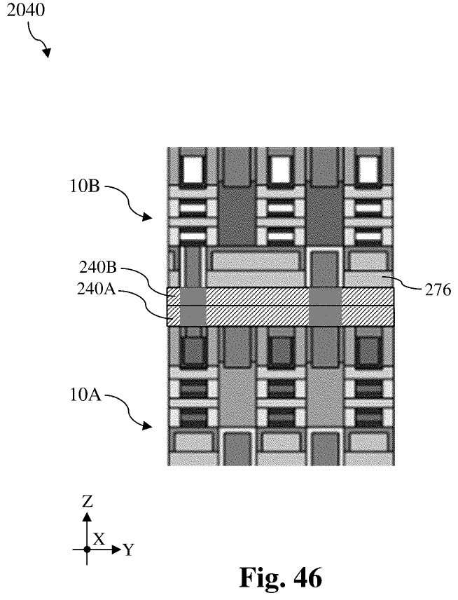

FIG. 46 illustrates a twentieth stacked device structure 2040. The 20^{th} stacked device structure 2040 is constructed according to the back-to-face scheme as a back side of the beta multi-gate device structure 10B is bonded to a front side of the alpha multi-gate device structure 10A by way of the first high-kappa dielectric layer 240A and the second high-kappa dielectric layer 240B.

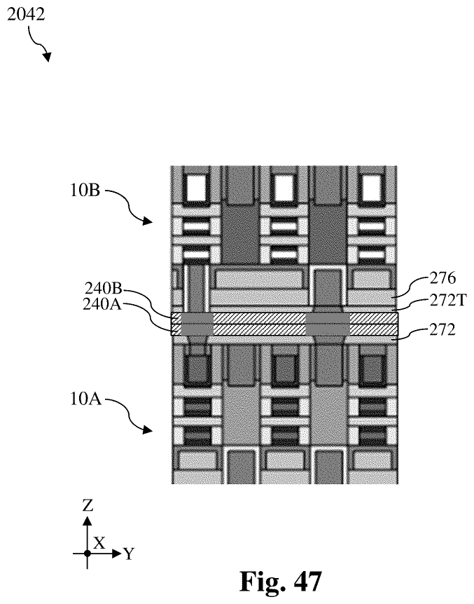

FIG. 47 illustrates a 21st stacked device structure 2042. The 21st stacked device structure 2042 is constructed according to the back-to-face scheme as a back side of the beta multi-gate device structure 10B is bonded to a front side of the alpha multi-gate device structure 10A by way of the first high-kappa dielectric layer 240A and the second high-kappa dielectric layer 240B. Compared to the twentieth stacked device structure 2040, an interface dielectric layer 272 is disposed between the alpha multi-gate device structure 10A and the first high-kappa dielectric layer 240A and a top interface dielectric layer 272T is disposed between the beta multi-gate device structure 10B and the second high-kappa dielectric layer 240B.

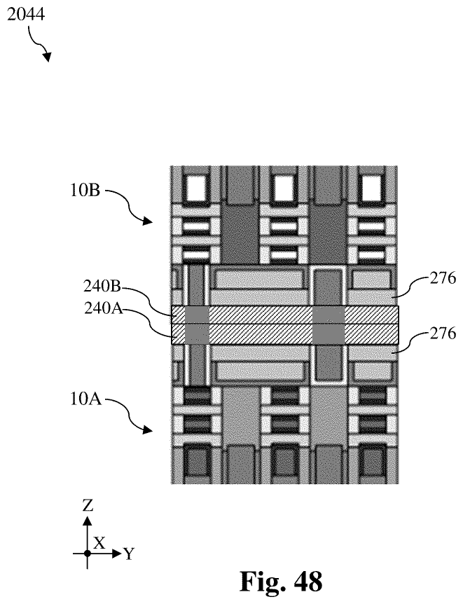

FIG. 48 illustrates a 22nd stacked device structure 2044. The 22nd stacked device structure 2044 is constructed according to the back-to-back scheme as a back side of the beta multi-gate device structure 10B is bonded to a back side of the alpha multi-gate device structure 10A by way of the first high-kappa dielectric layer 240A and the second high-kappa dielectric layer 240B.

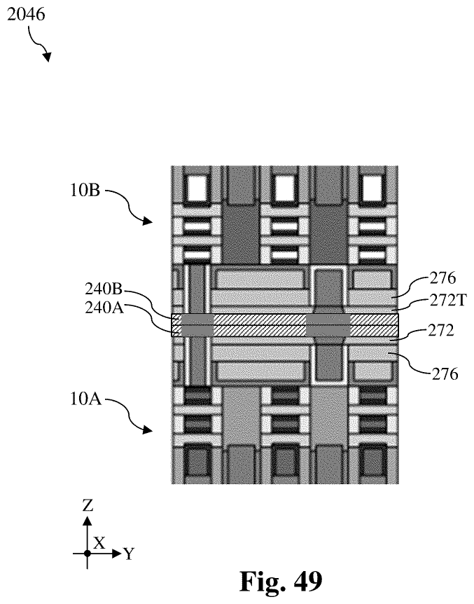

FIG. 49 illustrates a 23rd stacked device structure 2046. The 23rd stacked device structure 2046 is constructed according to the back-to-back scheme as a back side of the beta multi-gate device structure 10B is bonded to a back side of the alpha multi-gate device structure 10A by way of the first high-kappa dielectric layer 240A and the second high-kappa dielectric layer 240B. Compared to the 22nd stacked device structure 2044, an interface dielectric layer 272 is disposed between the alpha multi-gate device structure 10A and the first high-kappa dielectric layer 240A and a top interface dielectric layer 272T is disposed between the beta multi-gate device structure 10B and the second high-kappa dielectric layer 240B.

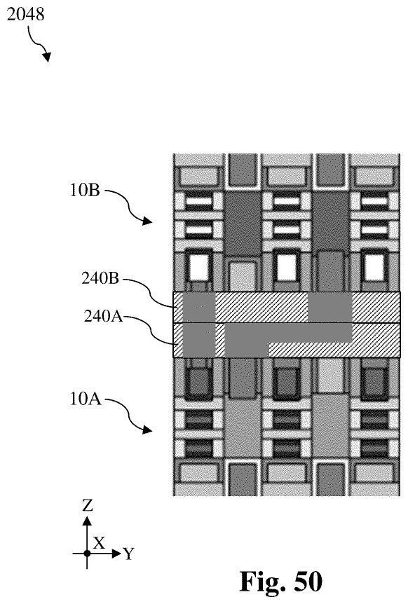

FIG. 50 illustrates a 24^{th} stacked device structure 2048. The 24th stacked device structure 2048 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B.

FIG. 51 illustrates a 25^{th} stacked device structure 2050. The 25^{th} stacked device structure 2050 is constructed according to the back-to-face scheme as a back side of the beta multi-gate device structure 10B is bonded to a front side of the alpha multi-gate device structure 10A by way of the first high-kappa dielectric layer 240A and the second high-kappa dielectric layer 240B.

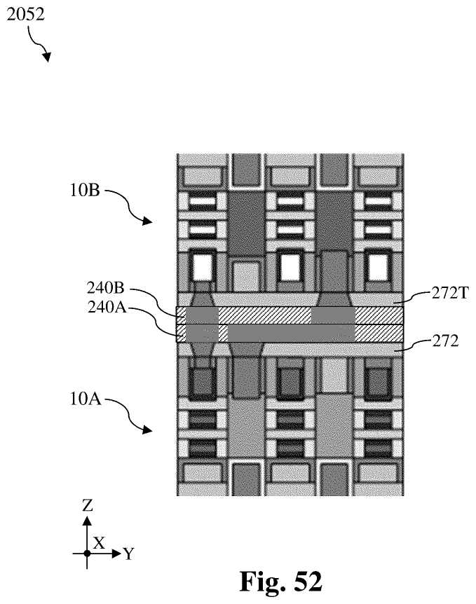

FIG. 52 illustrates a 26^{th} stacked device structure 2052. The 26^{th} stacked device structure 2052 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B. An interface dielectric layer 272 is disposed between the alpha multi-gate device structure 10A and the first high-kappa dielectric layer 240A and a top interface dielectric layer 272T is disposed between the beta multi-gate device structure 10B and the second high-kappa dielectric layer 240B.

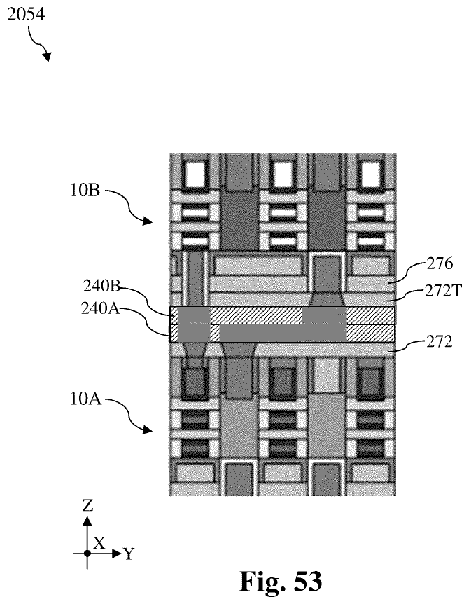

FIG. 53 illustrates a 27^{th} stacked device structure 2054. The 27^{th} stacked device structure 2054 is constructed according to the back-to-face scheme as a back side of the beta multi-gate device structure 10B is bonded to a front side of the alpha multi-gate device structure 10A by way of the first high-kappa dielectric layer 240A and the second high-kappa dielectric layer 240B. An interface dielectric layer 272 is disposed between the alpha multi-gate device structure 10A and the first high-kappa dielectric layer 240A and a top interface dielectric layer 272T is disposed between the beta multi-gate device structure 10B and the second high-kappa dielectric layer 240B.

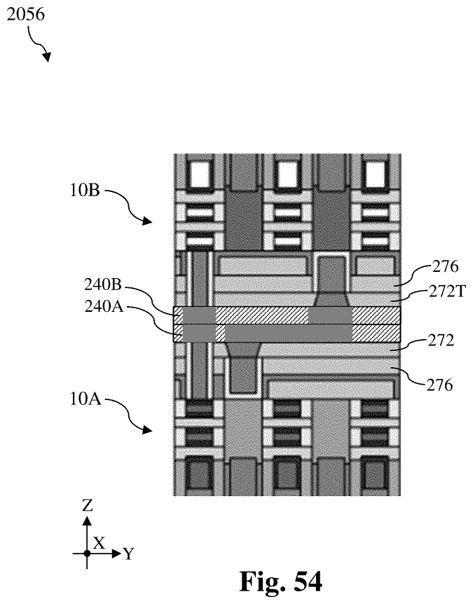

FIG. 54 illustrates a 28^{th} stacked device structure 2056. The 28^{th} stacked device structure 2056 is constructed according to the back-to-back scheme as a back side of the beta multi-gate device structure 10B is bonded to a back side of the alpha multi-gate device structure 10A by way of the first high-kappa dielectric layer 240A and the second high-kappa dielectric layer 240B. An interface dielectric layer 272 is disposed between the alpha multi-gate device structure 10A and the first high-kappa dielectric layer 240A and a top interface dielectric layer 272T is disposed between the beta multi-gate device structure 10B and the second high-kappa dielectric layer 240B.

Different from methods 100 and 300 above, method 400 forms a high-kappa dielectric layer over a first multi-gate device structure using a selective deposition process. In some implementations, the selective deposition process may be performed with patterning layers to pattern the high-kappa dielectric layer without etching the high-kappa dielectric layer.

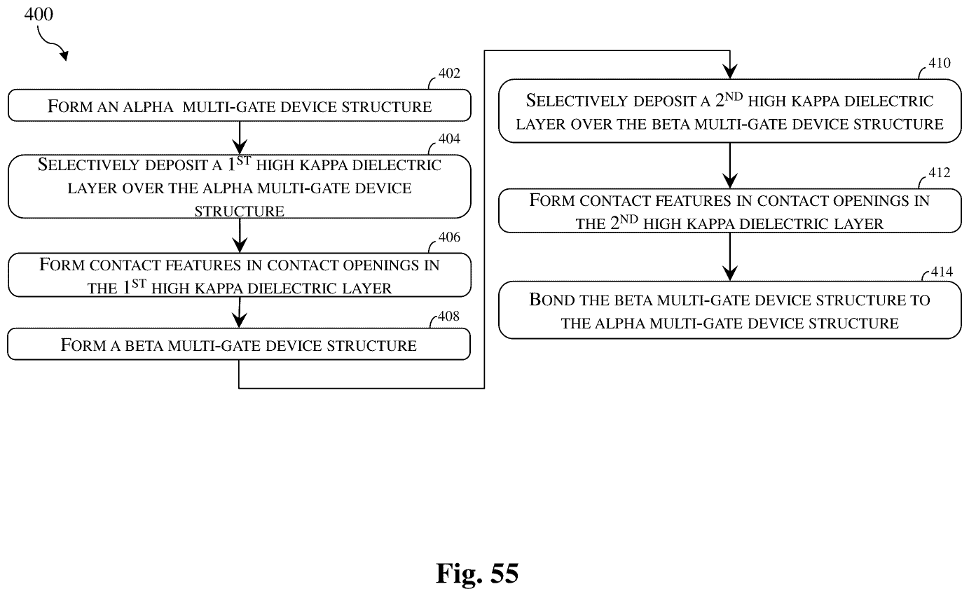

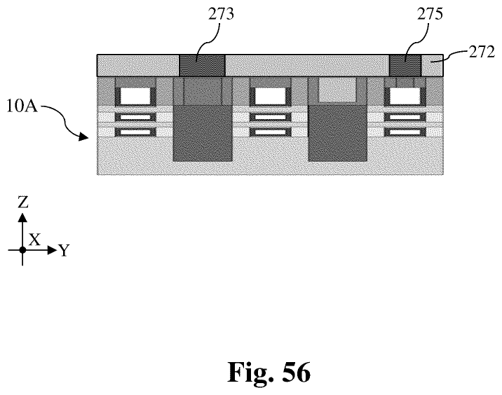

Referring to FIGS. 55 and 56, method 400 includes a block 402 where an alpha multi-gate device structure 10A is formed. Operations at block 402 are similar to those at block 102. Because the operations at block 102 have been described in detail above, a detailed description of operations at block 402 are omitted for brevity. As shown in FIG. 56, the alpha multi-gate device structure 10A includes an interface dielectric layer 272 and is similar to the alpha multi-gate device structure 10A shown in FIG. 24.

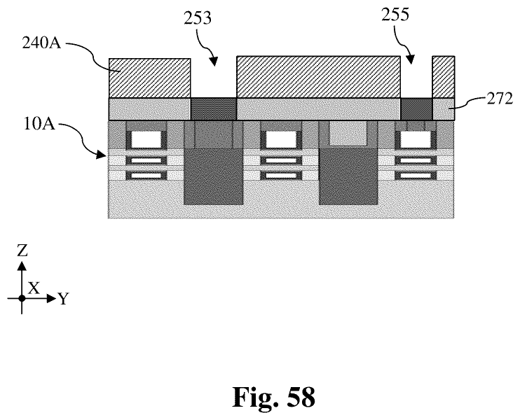

Referring to FIGS. 55, 57, and 58, method 400 includes a block 404 where a first high-kappa dielectric layer 240A is selectively deposited over the alpha multi-gate device structure 10A. In the depicted embodiments, when method 400 is adopted, the first high-kappa dielectric layer 240A includes diamond. Unlike operations at block 104 and 304, the first high-kappa dielectric layer 240A is deposited using selective growth, rather than a film transfer process. In an example process, a seed layer 2400 is first selectively deposited over a top surface of the interface dielectric layer 272 by ALD, chemical vapor transport (CVT), spin on coating or dipping into a nanodiamond solution. The deposition of the seed layer 2400 may be performed at a temperature between 0° C. and 300° C. The deposition of the seed layer 2400 may be referred to as nucleation or seeding and the seed layer 2400 may also be referred to as a nucleation layer 2400. In some alternative embodiments, the top surface of the interface dielectric layer 272 may be treated by plasma or wet treatments to enhance the selectivity of deposition. The plasma treatment may include use of hydrogen, oxygen, nitrogen, argon, or a mixture thereof. The wet treatment may use capping agents, hydrogen peroxide, sulfuric acids, hydrochloric acid, nitric acid, or a combination thereof. After seeding with the seed layer 2400, the first high-kappa dielectric layer 240A may be deposited using CVD, as illustrated in FIG. 58. In some embodiments, the precursor for the CVD process may include an adamantane structure. The precursor may include one or more functional groups on the adamantane structure. The functional groups may include a hydroxyl group, a carbonyl group, a carboxyl group, an amine group, a bromine group, a chlorine group, an iodine group, an acetate group, a methyl group, a sulfonyl group, an isocyanate group, a nitrile group, a cyano group, a thiocyanate group, a thiol group, an amide group, a phosphaethyne group, or a combination thereof. Skeletal formulae of example precursors are as follows:

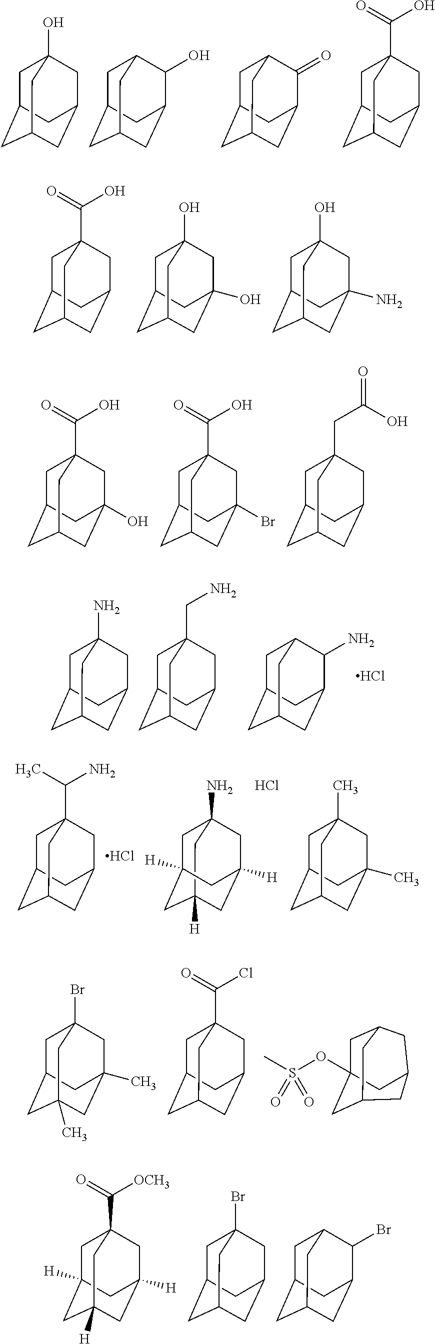

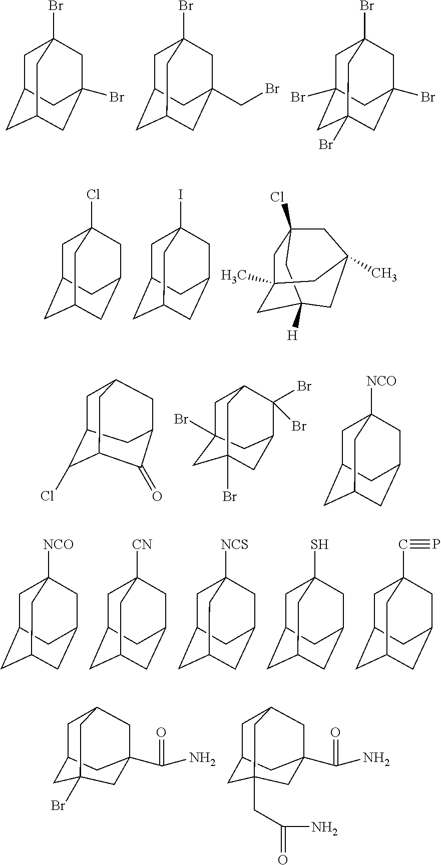

When method 400 is adopted, elements in the functional groups of the precursor may remain in the first high-kappa dielectric layer 240A, albeit in trace amounts. In other words, the first high-kappa dielectric layer 240A may include nitrogen, oxygen, sulfur, phosphorus, chlorine, bromine, iodine, or a combination thereof. As shown in FIG. 58, due to the selective nature of the deposition, contact openings 253 and 255 are formed in the as deposited first high-kappa dielectric layer 240A without any photolithography or etching steps.

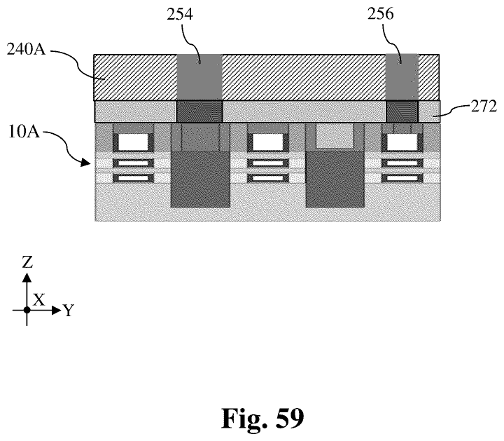

Referring to FIGS. 55 and 59, method 400 includes a block 406 where contact features are formed in the first high-kappa dielectric layer 240A. At block 406, a metal fill layer is deposited over the contact openings 253 and 255 using PVD or CVD. In some embodiments, the metal fill layer may include tungsten (W), molybdenum (Mo), ruthenium (Ru), cobalt (Co), nickel (Ni), copper (Cu), or a combination thereof. After deposition of the metal fill layer, a planarization process, such as a CMP process, is performed to form the contact features 254 and 256 in the first high-kappa dielectric layer 240A.

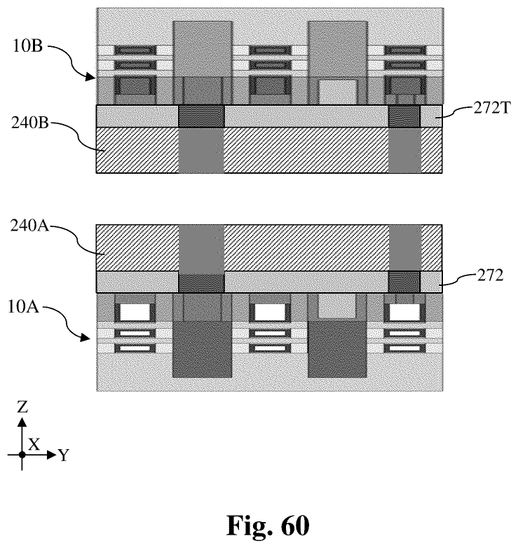

Referring to FIGS. 55 and 60, method 400 includes a block 408 where a beta multi-gate device structure 10B is formed. At block 408, operations at blocks 402, 404 and 406 are repeated before, simultaneously or subsequently to form a beta multi-gate device structure 10B. The beta multi-gate device structure 10B may be of a different conductivity type from the alpha multi-gate device structure 10A. In some embodiments, the alpha multi-gate device structure 10A includes n-type GAA devices and the beta multi-gate device structure 10B includes p-type GAA devices. In some alternative embodiments, the alpha multi-gate device structure 10A includes p-type GAA devices and the beta multi-gate device structure 10B includes n-type GAA devices. The beta multi-gate device structure 10B in FIG. 60 is similar to the beta multi-gate device structure 10B in FIG. 35.

Referring to FIGS. 55 and 60, method 400 includes a block 410 where a second high-kappa dielectric layer 240B is selectively deposited over the beta multi-gate device structure 10B. Formation of the second high-kappa dielectric layer 240B at block 410 may be similar to formation of the first high-kappa dielectric layer 240A at block 406. For this reason, a detailed description of operations at block 410 is omitted. Due to the selective nature of the deposition, contact openings are formed in the as deposited second high-kappa dielectric layer 240B without any photolithography or etching steps.

Referring to FIGS. 55 and 60, method 400 includes a block 412 where second contact features are formed in the second openings in the second high-kappa dielectric layer 240B. At block 412, a metal fill layer is deposited over the contact openings in the second high-kappa dielectric layer 240B using PVD or CVD. In some embodiments, the metal fill layer may include tungsten (W), molybdenum (Mo), ruthenium (Ru), cobalt (Co), nickel (Ni), copper (Cu), or a combination thereof. After deposition of the metal fill layer, a planarization process, such as a CMP process, is performed to form the contact features in the second high-kappa dielectric layer 240B.

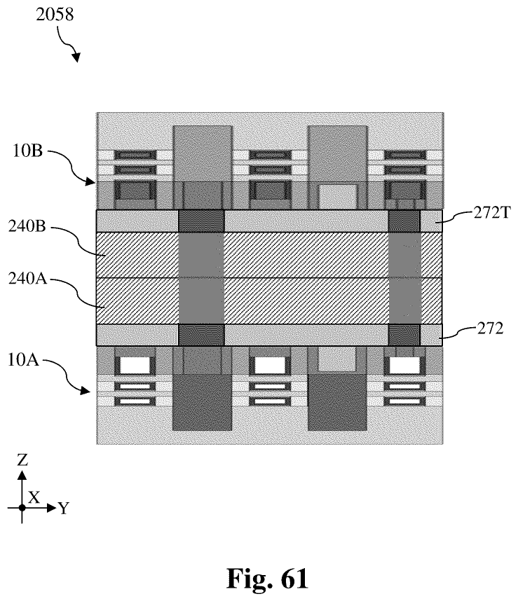

Referring to FIGS. 55, 60 and 61, method 400 includes a block 414 where the beta multi-gate device structure 10B is bonded to the alpha multi-gate device structure 10A. At block 414, the beta multi-gate device structure 10B is bonded to the alpha multi-gate device structure 10A by bonding the first high-kappa dielectric layer 240A to the second high-kappa dielectric layer 240B. To bond the first high-kappa dielectric layer 240A to the second high-kappa dielectric layer 240B, their exposed surfaces are first treated with a nitrogen (N₂) plasma, an oxygen (O₂) plasma, or an argon (Ar) plasma to introduce surface hydroxyl groups, amine groups, or other dangling bonds. After the treatment, the bonding surfaces may be cleaned with deionized (DI) water. In some alternative embodiments, before the plasma treatment, the first high-kappa dielectric layer 240A and the second high-kappa dielectric layer 240B may be optionally cleaned to remove organic and metallic contaminants. In an example process, a mixture of ammonium hydroxide and hydrogen peroxide (SC1) and/or a mixture of hydrochloric acid and hydrogen peroxide (SC2) may be used to clean surfaces of the first high-kappa dielectric layer 240A, the second high-kappa dielectric layer 240B, and the contact features. The mixture of ammonium hydroxide and hydrogen peroxide (SC1) may remove organic contaminants. The mixture of hydrochloric acid and hydrogen peroxide (SC2) may remove metallic contaminants. After the plasma treatment, the second high-kappa dielectric layer 240B is aligned with and put in direct contact with the first high-kappa dielectric layer 240A. The exposed surfaces of the contact features in the first high-kappa dielectric layer 240A and the second high-kappa dielectric layer 240B are also aligned. An anneal is performed to promote the covalent force bonding of the first high-kappa dielectric layer 240A to the second high-kappa dielectric layer 240B. At conclusion of operations at block 414, a 29^{th} stacked device structure 2058 is formed. The 29^{th} stacked device structure 2058 shown in FIG. 61 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B.

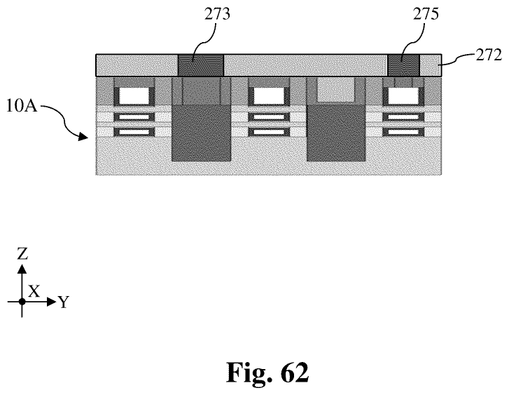

When the to-be-formed contact features are not fully aligned with the conductive features in the interface dielectric layer 272, a pattern film may be deposited to cover portions of the interface dielectric layer 272 or the first high-kappa dielectric layer 240A (or the second high-kappa dielectric layer 240B). Examples processes where a pattern film is implemented are illustrated in FIGS. 62-68 and 69-74.

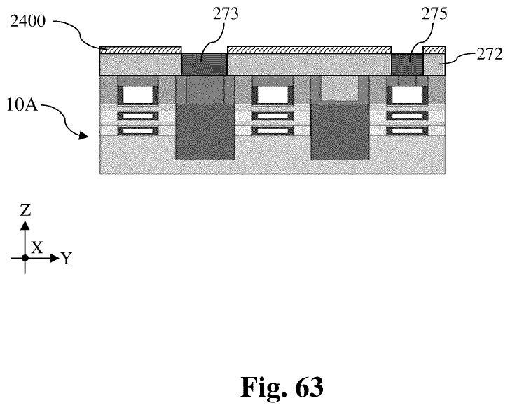

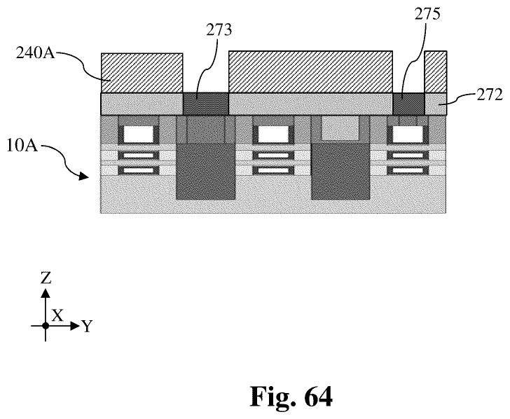

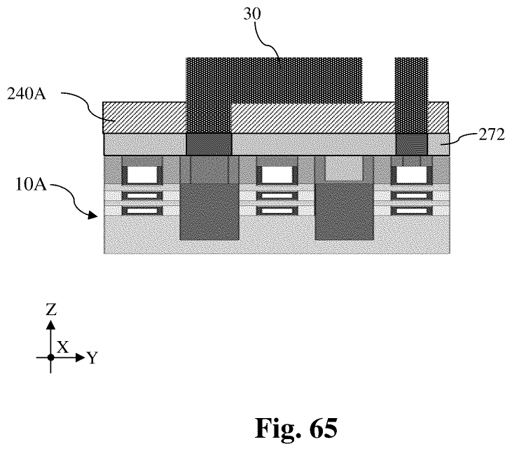

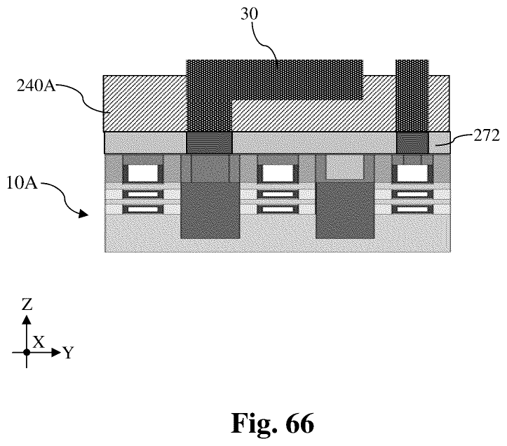

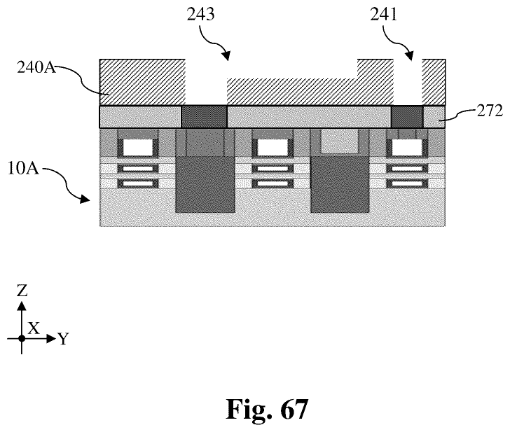

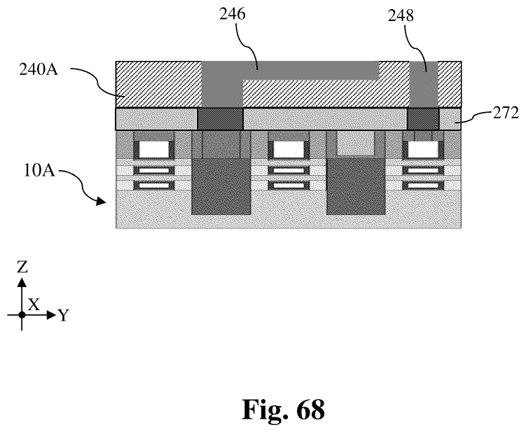

Reference is first made to FIGS. 62-68. FIG. 62 illustrates an alpha multi-gate device structure 10A that includes an interface dielectric layer 272. The first conductive feature 273 and the second conductive feature 275 are disposed in the interface dielectric layer 272. The alpha multi-gate device structure 10A is formed at block 402 of method 400. Method 400 then proceeds to block 404 where a seed layer 2400 is selectively deposited over the exposed surface of the interface dielectric layer 272, as shown in FIG. 63. In a first stage of selective deposition, a portion of the first high-kappa dielectric layer 240A is selectively deposited on the seed layer 2400, as shown in FIG. 64. A first pattern film 30 is then deposited to cover the first conductive feature 273, the second conductive feature 275, and a portion of the first high-kappa dielectric layer 240A, as shown in FIG. 65. The first pattern film 30 includes a photoresist or a bottom antireflective coating (BARC) layer and functions as a deposition mask as in a second stage of selective deposition the first high-kappa dielectric layer 240A, as illustrated in FIG. 66. After the two stages of selective deposition, the first pattern film 30 is selectively removed using ashing or selective etching. After the removal of the first pattern film 30, a two-tier contact opening 243 and a contact opening 241 are formed in the first high-kappa dielectric layer 240A. FIG. 68 illustrates formation of the first contact feature 246 and the second contact feature 248 in the contact openings 243 and 241 shown in FIG. 67. It should be understood that, while not explicitly shown in figures, similar operations may be performed to a beta multi-gate device structure 10B and the alpha and beta multi-gate device structures 10A and 10B may be bonded together by way of the first high-kappa dielectric layer 240A and the second high-kappa dielectric layer 240B.

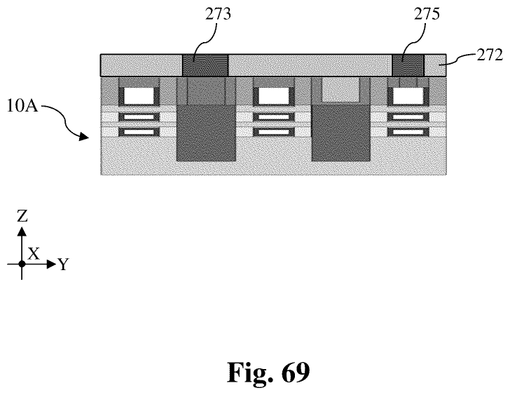

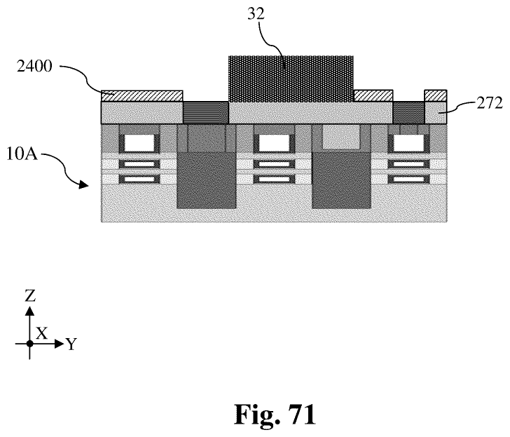

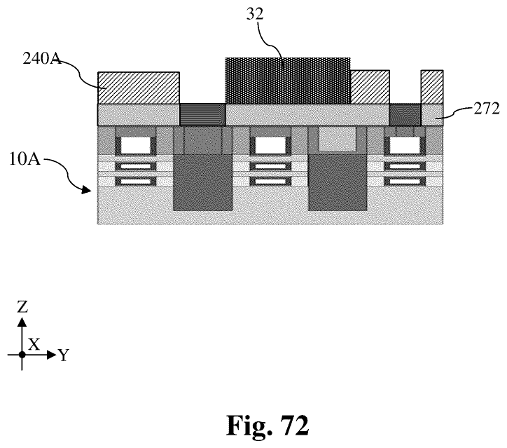

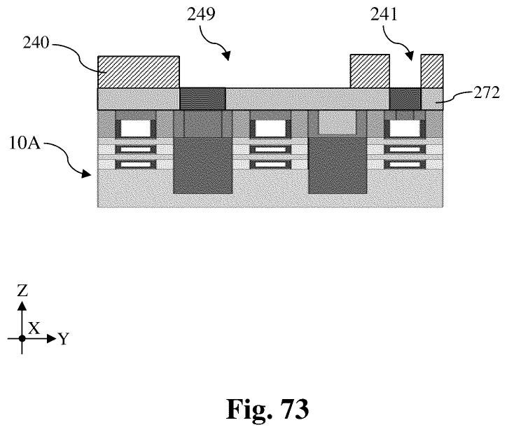

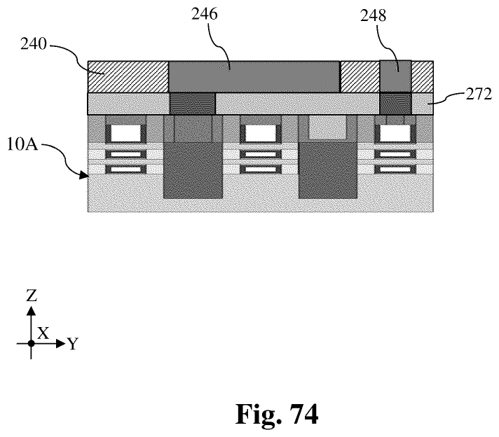

Reference is then made to FIGS. 69-74. FIG. 69 illustrates an alpha multi-gate device structure 10A that includes an interface dielectric layer 272. The first conductive feature 273 and the second conductive feature 275 are disposed in the interface dielectric layer 272. The alpha multi-gate device structure 10A is formed at block 402 of method 400. Method 400 then proceeds to block 404. Before a seed layer 2400 is selectively deposited over the exposed surface of the interface dielectric layer 272, a second pattern film 32 is formed over the interface dielectric layer 272. With the second pattern film 32 covering a portion of the interface dielectric layer 272, a seed layer 2400 is selectively deposited over an exposed portion of the interface dielectric layer 272, as illustrated in FIG. 71. As shown in FIG. 72, a selective growth of the first high-kappa dielectric layer 240A is performed. After the selective deposition of the first high-kappa dielectric layer 240A, the second pattern film 32 is selectively removed using ashing or selective etching. After the removal of the second pattern film 32, a long contact opening 249 and a contact opening 241 are formed in the first high-kappa dielectric layer 240A as shown in FIG. 73. FIG. 74 illustrates formation of contact features 246 and 248 in the contact openings 249 and 241. It should be understood that, while not explicitly shown in figures, similar operations may be performed to a beta multi-gate device structure 10B and the alpha and beta multi-gate device structures 10A and 10B may be bonded together by way of the first high-kappa dielectric layer 240A and the second high-kappa dielectric layer 240B.

Method 500 forms a high-kappa dielectric layer over a first multi-gate device structure and the high-kappa dielectric layer includes contact openings. At method 500, contact openings are widened and rounded to improve process window.

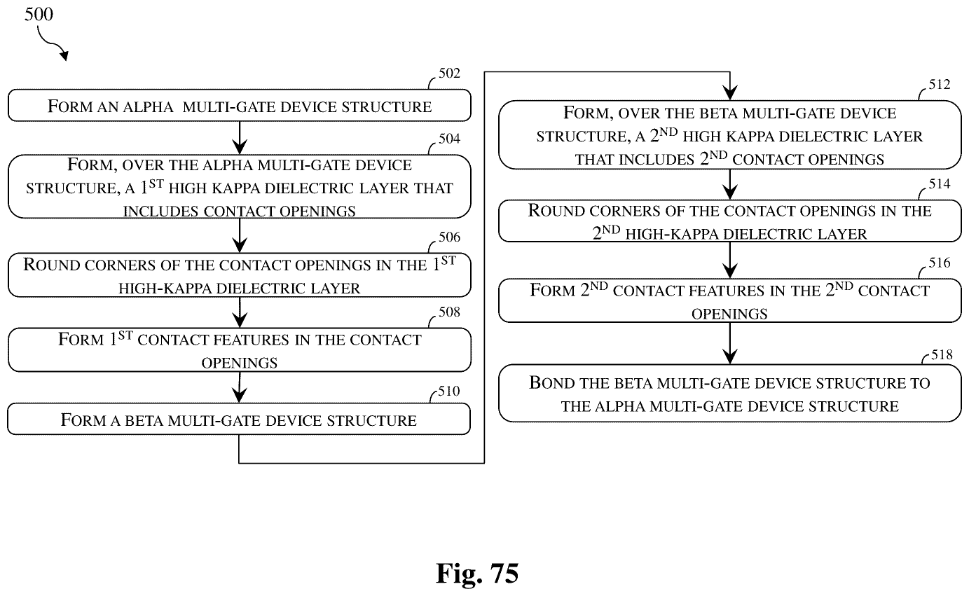

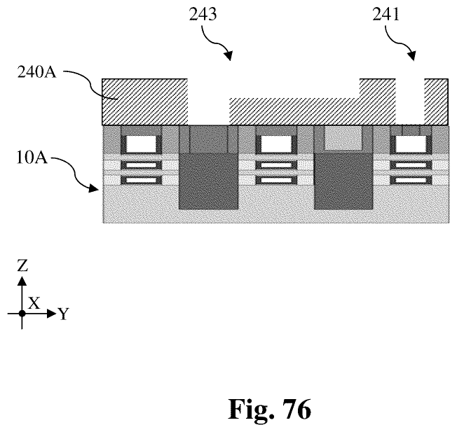

Referring to FIGS. 75 and 76, method 500 include a block 502 where an alpha multi-gate device structure 10A is formed. Operations at block 502 are similar to those at block 102. Because the operations at block 102 have been described in detail above, a detailed description of operations at block 502 are omitted for brevity.

Referring to FIGS. 75 and 76, method 500 includes a block 504 where the first high-kappa dielectric layer 240A is formed over the alpha multi-gate device structure 10A. At block 504, the first high-kappa dielectric layer 240A may be deposited and patterned following operations similar to those at blocks 304 and 306 of method 300. In some alternative embodiments, the first high-kappa dielectric layer 240A may be formed over the alpha multi-gate device structure 10A following selective deposition operations similar to those at block 404 of method 400. In the depicted embodiments, the first high-kappa dielectric layer 240A formed at block 504 may include contact openings 243 and 241.

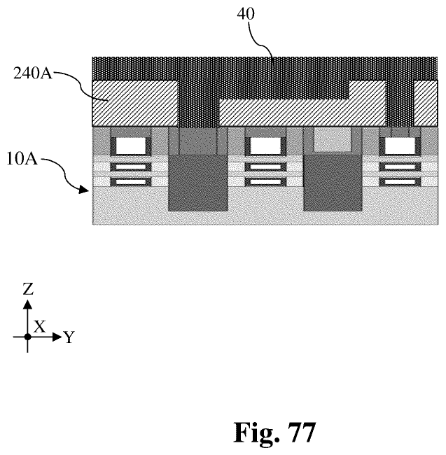

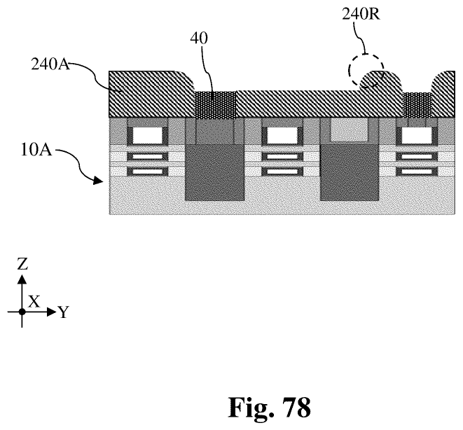

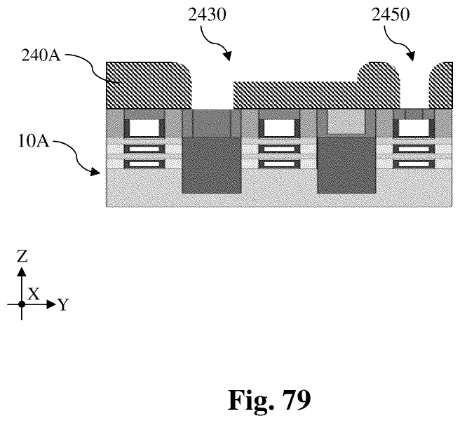

Referring to FIGS. 75 and 77-79, method 500 includes a block 506 where corners of the contact openings are rounded. In some embodiments, the corner routing operations may be performed with use of a patterning film and directional etching. In the depicted embodiments, a third pattern film 40 is deposited over the first high-kappa dielectric layer 240A, including over the contact openings 243 and 241, as shown in FIG. 77. In some implementations, the third pattern film 40 may include photoresist or a BARC layer. As shown in FIG. 78, an anisotropic etch 600 is performed with use of argon, hydrogen, oxygen, chlorine, boron trichloride, carbon tetrafluoride (CF₄), methane, trifluoromethane, or sulfur hexafluoride. The anisotropic etch 600 is configured to etch the first high-kappa dielectric layer 240A at a slower rate such that it primarily removes shape edges at the corners of the openings. As a result, the anisotropic etch 600 removes a portion of the third pattern film 40 and forms rounded corners 240R as shown in FIG. 78. After the corners of the openings are rounded, the third pattern film 40 is removed by ashing or selective etching, leaving behind rounded-corner openings 2430 and 2450, shown in FIG. 79.

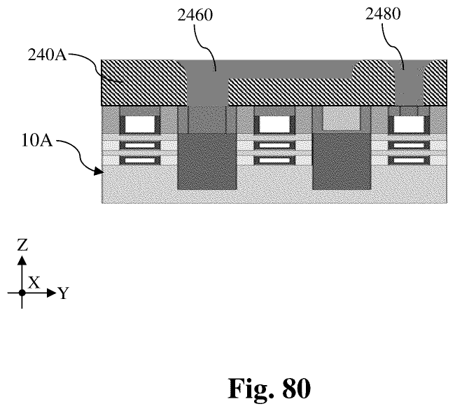

Referring to FIGS. 75 and 80, method 500 includes a block 508 wherein contact features are formed in the contact openings in the first high-kappa dielectric layer 240A. At block 508, a metal fill layer is deposited over the contact openings in the first high-kappa dielectric layer 240A using PVD or CVD. In some embodiments, the metal fill layer may include tungsten (W), molybdenum (Mo), ruthenium (Ru), cobalt (Co), nickel (Ni), copper (Cu), or a combination thereof. After deposition of the metal fill layer, a planarization process, such as a CMP process, is performed to form the contact features 2460 and 2480 in the first high-kappa dielectric layer 240A. The rounded-corners 240R allow top surfaces of the contact features 2460 and 2480 to be widened. The widened contact features 2460 and 2480 may widen the alignment process window and reduce contact resistance.

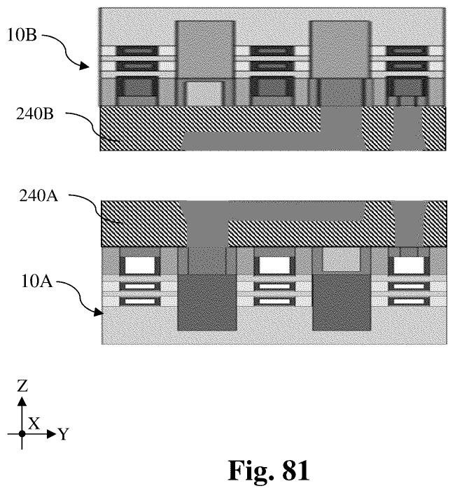

Referring to FIGS. 75 and 81, method 500 includes a block 510 where a second multi-gate device structure 10B is formed. At block 408, operations at blocks 402, 404 and 406 are repeated before, simultaneously or subsequently to form a beta multi-gate device structure 10B. The beta multi-gate device structure 10B may be of a different conductivity type from the alpha multi-gate device structure 10A. In some embodiments, the alpha multi-gate device structure 10A includes n-type GAA devices and the beta multi-gate device structure 10B includes p-type GAA devices. In some alternative embodiments, the alpha multi-gate device structure 10A includes p-type GAA devices and the beta multi-gate device structure 10B includes n-type GAA devices.

Referring to FIGS. 75 and 81, method 500 includes a block 512 where the second high-kappa dielectric layer 240B is formed over the second multi-gate device structure 10B. Formation of the second high-kappa dielectric layer 240B at block 512 may be similar to formation of the first high-kappa dielectric layer 240A at block 504. A detailed description of operations at block 512 is omitted for brevity. The second high-kappa dielectric layer 240A includes contact openings.

Referring to FIGS. 75 and 81, method 500 includes a block 514 where corners of the contact openings in the second high-kappa dielectric layer 240B are rounded. At block 514, operations similar to those described above with regards to block 506 are performed with respect to the second high-kappa dielectric layer 240B on the beta multi-gate device structure 10B. For brevity, a detailed description of the operations at block 514 is omitted.

Referring to FIGS. 75 and 81, method 500 includes a block 516 where contact features are formed in the contact openings in the second high-kappa dielectric layer 240B. At block 516, a metal fill layer is deposited over the contact openings in the second high-kappa dielectric layer 240B using PVD or CVD. In some embodiments, the metal fill layer may include tungsten (W), molybdenum (Mo), ruthenium (Ru), cobalt (Co), nickel (Ni), copper (Cu), or a combination thereof. After deposition of the metal fill layer, a planarization process, such as a CMP process, is performed to form the contact features in the second high-kappa dielectric layer 240B.

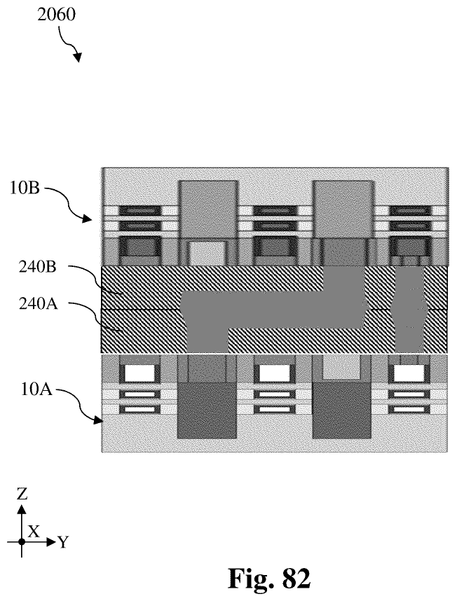

Referring to FIGS. 75 and 82, method 500 includes a block 518 where the beta multi-gate device structure 10B is bonded to the alpha multi-gate device structure 10A. At block 518, the beta multi-gate device structure 10B is bonded to the alpha multi-gate device structure 10A by bonding the first high-kappa dielectric layer 240A to the second high-kappa dielectric layer 240B. To bond the first high-kappa dielectric layer 240A to the second high-kappa dielectric layer 240B, their exposed surfaces are first treated with a nitrogen (N₂) plasma, an oxygen (O₂) plasma, or an argon (Ar) plasma to introduce surface hydroxyl groups, amine groups, or other dangling bonds. After the treatment, the bonding surfaces may be cleaned with deionized (DI) water. In some alternative embodiments, before the plasma treatment, the first high-kappa dielectric layer 240A and the second high-kappa dielectric layer 240B may be optionally cleaned to remove organic and metallic contaminants. In an example process, a mixture of ammonium hydroxide and hydrogen peroxide (SC1) and/or a mixture of hydrochloric acid and hydrogen peroxide (SC2) may be used to clean surfaces of the first high-kappa dielectric layer 240A, the second high-kappa dielectric layer 240B, and the contact features. The mixture of ammonium hydroxide and hydrogen peroxide (SC1) may remove organic contaminants. The mixture of hydrochloric acid and hydrogen peroxide (SC2) may remove metallic contaminants. After the plasma treatment, the second high-kappa dielectric layer 240B is aligned with and put in direct contact with the first high-kappa dielectric layer 240A. The exposed surfaces of the contact features in the first high-kappa dielectric layer 240A and the second high-kappa dielectric layer 240B are also aligned. An anneal is performed to promote the covalent bonding of the first high-kappa dielectric layer 240A to the second high-kappa dielectric layer 240B. At conclusion of operations at block 518, a 30^{th} stacked device structure 2060 is formed. The 30^{th} stacked device structure 2060 shown in FIG. 82 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B.

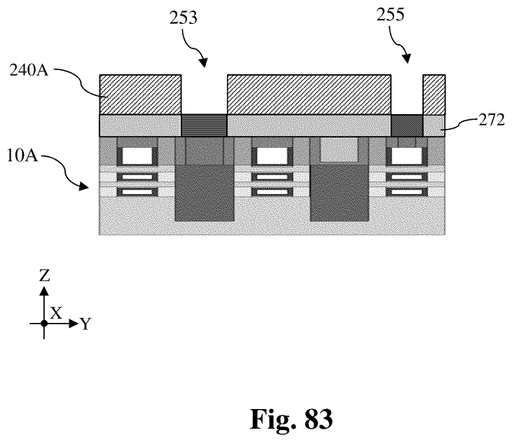

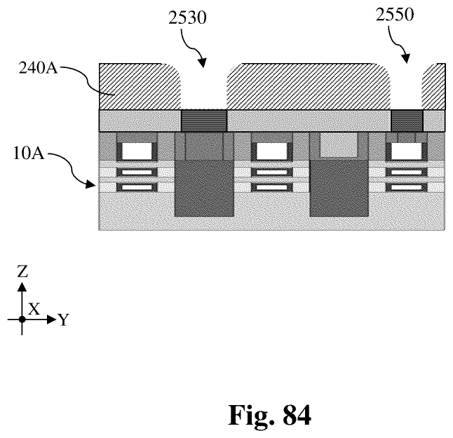

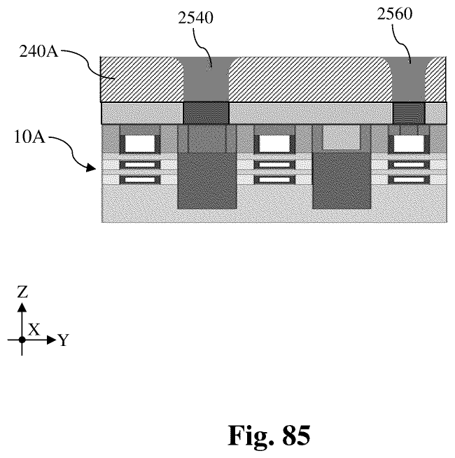

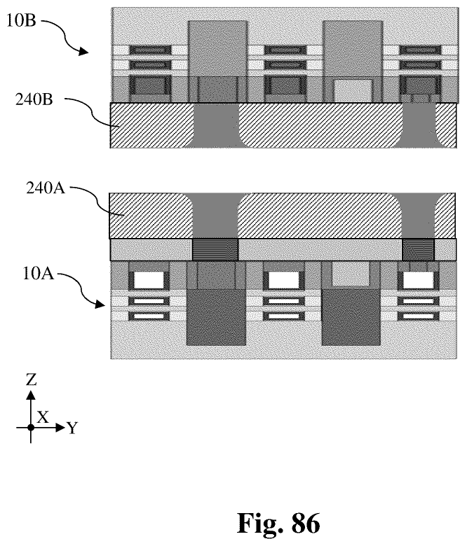

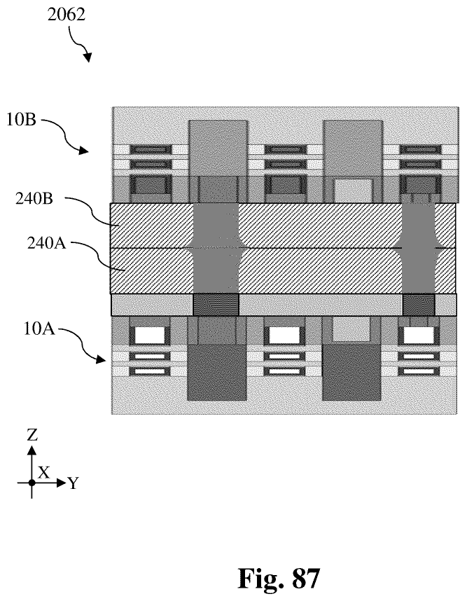

FIGS. 83-87 illustrates an alternative embodiment when steps in method 500 are followed. FIG. 83 illustrates an alpha multi-gate device structure 10A formed at block 502 of method 500. The alpha multi-gate device structure 10A in FIG. 83 includes an interface dielectric layer 272. Conductive features 273 and 275 are disposed in the interface dielectric layer 272. The first high-kappa dielectric layer 240A in FIG. 83 may be formed following operations a block 504. In the depicted embodiment, the first high-kappa dielectric layer 240A in FIG. 83 includes contact openings 253 and 255. Reference is made to FIG. 84, corners of the contact openings 253 and 255 are rounded using operations at block 506, thereby forming rounded-corner openings 2530 and 2550. At block 508, a metal fill is deposited in the rounded-corner openings 2530 and 2550 to form contact features 2540 and 2560 in the first high-kappa dielectric layer 240A, as shown in FIG. 85. Operations at blocks 510-516 are then performed to form a second high-kappa dielectric layer 240B bonded to a second multi-gate device structure 10B. The first high-kappa dielectric layer 240A and the second high-kappa dielectric layer 240B are then aligned as shown in FIG. 86 and bonded together as shown in FIG. 87 to form a 31^{st} stacked device structure 2062. The 31^{st} stacked device structure 2062 shown in FIG. 87 is constructed according to the face-to-face scheme as a front side of the beta multi-gate device structure 10B is bonded to a front side of the alpha multi-gate device structure 10A by way of the first high-kappa dielectric layer 240A and the second high-kappa dielectric layer 240B.

In one exemplary aspect, the present disclosure is directed to a method. The method includes forming a first multi-gate device structure, depositing a high-kappa dielectric layer over a substrate, bonding the high-kappa dielectric layer over the first multi-gate device structure, after the bonding of the high-kappa dielectric layer, removing the substrate, patterning the high-kappa dielectric layer to form a contact opening, forming a contact feature in the contact opening, bonding an epitaxial stack over the high-kappa dielectric layer and the contact feature, and performing further processes to form a second multi-gate device structure from the epitaxial stack. The epitaxial stack includes a plurality of first semiconductor layers interleaved by a plurality of second semiconductor layers.

In some embodiments, the high-kappa dielectric layer includes diamond, boron nitride, aluminum nitride, aluminum boron nitride, or boron arsenide. In some embodiments, the substrate includes silicon, silicon carbide, sapphire, or magnesium oxide. In some instances, the removing includes a planarization process, a wet etch process, a dry etch process, or a debonding process. In some embodiments, the depositing of the high-kappa dielectric layer includes a chemical vapor deposition (CVD) process, a physical vapor deposition (PVD) process, or a physical vapor transport (PVT) process. In some implementations, the method further includes before the bonding, depositing a dielectric layer over the first multi-gate device structure. The dielectric layer includes silicon nitride, silicon oxide, silicon carbide, silicon oxynitride, silicon oxycarbide, silicon oxycarbonitride, boron oxide, boron oxynitride, aluminum oxide, aluminum oxynitride, arsenic oxide, or arsenic oxynitride. In some embodiments, the first multi-gate device structure includes a first source/drain feature, a second source/drain feature, a plurality of nanostructures extending between the first source/drain feature and the second source/drain feature, and a gate structure wrapping around each of the plurality of nanostructures. The gate structure includes a titanium-based material. In some embodiments, a bonding dielectric layer is deposited over a surface of the epitaxial stack. The bonding of the epitaxial stack over the high-kappa dielectric layer includes bonding the bonding dielectric layer to the high-kappa dielectric layer and the contact feature.

In another exemplary aspect, the present disclosure is directed to a method. The method includes forming a first multi-gate device structure, depositing a first dielectric layer over the first multi-gate device structure, forming a first contact feature in the first dielectric layer, selectively depositing a first nucleation layer over the first dielectric layer, performing a first selective growth of a high-kappa dielectric material over the first nucleation layer, depositing a first patterning film over the first contact feature to cover a portion of the high-kappa dielectric material, performing a second selective growth of the high-kappa dielectric material over the high-kappa dielectric material not covered by the first patterning film, and selectively removing the first patterning film to form a first contact opening, depositing a first metal fill in the first contact opening to form a second contact feature. The second contact feature interfaces the first contact feature.

In some embodiments, the first multi-gate device structure includes a first source/drain feature, a second source/drain feature, a plurality of nanostructures extending between the first source/drain feature and the second source/drain feature, and a gate structure wrapping around each of the plurality of nanostructures. The gate structure includes a titanium-based material. In some implementations, the first patterning film includes a bottom antireflective coating (BARC) film. In some instances, the first selective growth and the second selective growth include use of a precursor that includes an adamantane structure. In some embodiments, the precursor further includes a hydroxyl group, a carbonyl group, a carboxyl group, an amine group, a bromine group, a chlorine group, an iodine group, an acetate group, a methyl group, a sulfonyl group, an isocyanate group, a nitrile group, a cyano group, a thiocyanate group, a thiol group, an amide group, or a phosphacthyne group. In some embodiments, the high-kappa dielectric material includes diamond and a trace amount of nitrogen, oxygen, sulfur, phosphorus, chlorine, bromine, or iodine. In some implementations, the method further includes forming a second multi-gate device structure, depositing a second dielectric layer over the second multi-gate device structure, forming a third contact feature in the second dielectric layer, selectively depositing a second nucleation layer over the second dielectric layer, performing a third selective growth of the high-kappa dielectric material over the second nucleation layer, depositing a second patterning film over the third contact feature to cover a portion of the high-kappa dielectric material over the second dielectric layer, performing a fourth selective growth of the high-kappa dielectric material over the high-kappa dielectric material not covered by the second patterning film, selectively removing the second patterning film to form a second contact opening, depositing a second metal fill in the second contact opening to form a fourth contact feature, and bonding the second multi-gate device structure to the first multi-gate device structure such that the fourth contact feature is aligned with and interfaces the second contact feature.

In yet another exemplary aspect, the present disclosure is directed to a method. The method includes forming a first multi-gate device structure having a first contact feature, form a high-kappa dielectric layer over the first multi-gate device structure,
patterning the high-kappa dielectric layer to form a contact opening that exposes the first contact feature, depositing a patterning film over the high-kappa dielectric layer and the contact opening, after the depositing of the patterning film, performing a dry etch process to widen the contact opening while the first contact feature remains covered by the patterning film, selectively removing the patterning film, and depositing a metal fill over the widened contact opening to form a second contact feature to interface the first contact feature.

In some embodiments, the forming of the high-kappa dielectric layer includes depositing the high-kappa dielectric layer over a substrate, after the depositing of the high-kappa dielectric layer, bonding the high-kappa dielectric layer to the first multi-gate device structure, and after the bonding, selectively removing the substrate. In some implementations, the substrate includes silicon, silicon carbide, sapphire, or magnesium oxide. In some embodiments, the high-kappa dielectric layer includes diamond, boron nitride, aluminum nitride, aluminum boron nitride, or boron arsenide. In some implementations, the first multi-gate device structure includes a first source/drain feature, a second source/drain feature, a plurality of nanostructures extending between the first source/drain feature and the second source/drain feature, and a gate structure wrapping around each of the plurality of nanostructures.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first multi-gate device structure;
depositing a high-kappa dielectric layer over a substrate;
bonding the high-kappa dielectric layer over the first multi-gate device structure;
after the bonding of the high-kappa dielectric layer, removing the substrate;
patterning the high-kappa dielectric layer to form a contact opening;
forming a contact feature in the contact opening;
bonding an epitaxial stack over the high-kappa dielectric layer and the contact feature; and
performing further processes to form a second multi-gate device structure from the epitaxial stack,
wherein the epitaxial stack comprises a plurality of first semiconductor layers interleaved by a plurality of second semiconductor layers.

2. The method of claim 1, wherein the high-kappa dielectric layer comprises diamond, boron nitride, aluminum nitride, aluminum boron nitride, or boron arsenide.

3. The method of claim 1, wherein the substrate comprises silicon, silicon carbide, sapphire, or magnesium oxide.

4. The method of claim 1, wherein the removing comprises a planarization process, a wet etch process, a dry etch process, or a debonding process.

5. The method of claim 1, wherein the depositing of the high-kappa dielectric layer comprises a chemical vapor deposition (CVD) process, a physical vapor deposition (PVD) process, or a physical vapor transport (PVT) process.

6. The method of claim 1, further comprising:
before the bonding, depositing a dielectric layer over the first multi-gate device structure,
wherein the dielectric layer comprises silicon nitride, silicon oxide, silicon carbide, silicon oxynitride, silicon oxycarbide, silicon oxycarbonitride, boron oxide, boron oxynitride, aluminum oxide, aluminum oxynitride, arsenic oxide, or arsenic oxynitride.

7. The method of claim 1,
wherein the first multi-gate device structure comprises:
a first source/drain feature,
a second source/drain feature,
a plurality of nanostructures extending between the first source/drain feature and the second source/drain feature, and
a gate structure wrapping around each of the plurality of nanostructures,
wherein the gate structure comprises a titanium-based material.

8. The method of claim 1,
wherein a bonding dielectric layer is deposited over a surface of the epitaxial stack,
wherein the bonding of the epitaxial stack over the high-kappa dielectric layer comprises bonding the bonding dielectric layer to the high-kappa dielectric layer and the contact feature.

9. A method, comprising:
forming a first multi-gate device structure;
depositing a first dielectric layer over the first multi-gate device structure;
forming a first contact feature in the first dielectric layer;
selectively depositing a first nucleation layer over the first dielectric layer;
performing a first selective growth of a high-kappa dielectric material over the first nucleation layer;
depositing a first patterning film over the first contact feature to cover a portion of the high-kappa dielectric material;
performing a second selective growth of the high-kappa dielectric material over the high-kappa dielectric material not covered by the first patterning film;
selectively removing the first patterning film to form a first contact opening; and
depositing a first metal fill in the first contact opening to form a second contact feature,
wherein the second contact feature interfaces the first contact feature.

10. The method of claim 9, wherein the first multi-gate device structure comprises:
a first source/drain feature,
a second source/drain feature,
a plurality of nanostructures extending between the first source/drain feature and the second source/drain feature, and
a gate structure wrapping around each of the plurality of nanostructures, wherein the gate structure comprises a titanium-based material.

11. The method of claim 9, wherein the first patterning film comprises a bottom antireflective coating (BARC) film.

12. The method of claim 9, wherein the first selective growth and the second selective growth comprise use of a precursor that includes an adamantane structure.

13. The method of claim 12, wherein the precursor further comprises a hydroxyl group, a carbonyl group, a carboxyl group, an amine group, a bromine group, a chlorine group, an iodine group, an acetate group, a methyl group, a sulfonyl group, an isocyanate group, a nitrile group, a cyano group, a thiocyanate group, a thiol group, an amide group, or a phosphaethyne group.

14. The method of claim 9, wherein the high-kappa dielectric material comprises diamond and a trace amount of nitrogen, oxygen, sulfur, phosphorus, chlorine, bromine, or iodine.

15. The method of claim 9, further comprising:
forming a second multi-gate device structure;
depositing a second dielectric layer over the second multi-gate device structure;
forming a third contact feature in the second dielectric layer;
selectively depositing a second nucleation layer over the second dielectric layer;
performing a third selective growth of the high-kappa dielectric material over the second nucleation layer;
depositing a second patterning film over the third contact feature to cover a portion of the high-kappa dielectric material over the second dielectric layer;
performing a fourth selective growth of the high-kappa dielectric material over the high-kappa dielectric material not covered by the second patterning film;
selectively removing the second patterning film to form a second contact opening;
depositing a second metal fill in the second contact opening to form a fourth contact feature; and
bonding the second multi-gate device structure to the first multi-gate device structure such that the fourth contact feature is aligned with and interfaces the second contact feature.

16. A method, comprising:
forming a first multi-gate device structure having a first contact feature;
form a high-kappa dielectric layer over the first multi-gate device structure;
patterning the high-kappa dielectric layer to form a contact opening that exposes the first contact feature;
depositing a patterning film over the high-kappa dielectric layer and the contact opening;
after the depositing of the patterning film, performing a dry etch process to widen the contact opening while the first contact feature remains covered by the patterning film;
selectively removing the patterning film; and
depositing a metal fill over the widened contact opening to form a second contact feature to interface the first contact feature.

17. The method of claim 16, wherein the forming of the high-kappa dielectric layer comprises:
depositing the high-kappa dielectric layer over a substrate;
after the depositing of the high-kappa dielectric layer, bonding the high-kappa dielectric layer to the first multi-gate device structure; and
after the bonding, selectively removing the substrate.

18. The method of claim 17, wherein the substrate comprises silicon, silicon carbide, sapphire, or magnesium oxide.

19. The method of claim 16, wherein the high-kappa dielectric layer comprises diamond, boron nitride, aluminum nitride, aluminum boron nitride, or boron arsenide.

20. The method of claim 16, wherein the first multi-gate device structure comprises:
a first source/drain feature,
a second source/drain feature,
a plurality of nanostructures extending between the first source/drain feature and the second source/drain feature, and
a gate structure wrapping around each of the plurality of nanostructures.
